(19) United States
(12) Patent Application Publication
(10) Pub. No.: US 2012/0126222 A1
(43) Pub. Date: May 24, 2012

(54) ORGANIC ELECTROLUMINESCENT ELEMENT

(75) Inventors: Toshinari Ogiwara, Sodegaura-shi (JP); Kazuki Nishimura, Sodegaura-shi (JP); Hiroyuki Saito, Sodegaura-shi (JP)

(73) Assignee: IDEMITSU KOSAN CO., LTD., Tokyo (JP)

(21) Appl. No.: 13/388,576

(22) PCT Filed: Jul. 5, 2011
(86) PCT No.: PCT/JP2011/065338

§ 371 Date: Feb. 2, 2012

(30) Foreign Application Priority Data
Jul. 12, 2010 (JP) 2010-158320

(51) Int. Cl. H01L 51/54

(52) U.S. Cl. 257/40; 257/E51.026

(57) ABSTRACT

An organic electroluminescence device includes an anode, an emitting layer, an electron transporting zone and a cathode in sequential order. A blocking layer is provided in the electron transporting zone adjacently to the emitting layer. The blocking layer contains a fused hydrocarbon compound and at least one compound selected from an electron-donating dopant and an organic metal complex that contains an alkali metal. A triplet energy of the fused hydrocarbon compound is 2.0 eV or more.

### TECHNICAL FIELD

The present invention relates to an organic electroluminescence device.

### BACKGROUND ART

When voltage is applied to an organic electroluminescence device (hereinafter, occasionally referred to as an organic EL device), holes are injected from an anode and electrons are injected from a cathode. The holes and the electrons are recombined in an emitting layer to form excitons. At this time, according to the electron spin statistics theory, singlet excitons and triplet excitons are generated at a ratio of 25%:75%. Emission from singlet excitons is defined as “fluorescent emission” and emission from triplet excitons is defined as “phosphorescent emission.” Since it has been considered that fluorescent emission is achievable by only singlet excitons, an internal quantum efficiency of the fluorescent emission is believed to be 25% at the maximum. On the other hand, since singlet exciton energy is also converted into triplet excitons by spin conversion in luminescent molecules for phosphorescent emission, theoretically, a nearly 100% internal luminous efficiency is expected to be obtained. Accordingly, a phosphorescent device has drawn attention as technology for a highly efficient organic EL device since a phosphorescent device with an Ir complex was reported by Forrest et al. in 2000.

However, a blue-emitting phosphorescent device is disadvantageous in lifetime, which hampers practical use of the device. For this reason, in a three-color device such as a full color display for a mobile phone, a TV set and the like, technology of combining a fluorescent device and a phosphorescent device has been demanded.

As technology for a fluorescent device with a high efficiency, technology to acquire emission from triplet excitons that have hitherto been not effectively utilized is disclosed. For instance, in non-Patent Literature 1, a non-doped device using an anthracene compound as a host is analyzed. In the mechanism, it is observed as delayed luminescence that a singlet exciton is generated by collision and fusion of two triplet excitons in an emitting layer. However, a device design to efficiently obtain emission from triplet excitons has still been a research task.

Various studies on the research task have been made.

Patent Literature 1 discloses a technology of lowering drive voltage, improving luminescence intensity and prolonging a lifetime of a fluorescent organic EL device by providing an electron injecting zone in the organic EL device. In the electron injecting zone, a metal atom represented by Li or Na is mixed as a reduction-causing dopant in an electron transporting material having an anthracene skeleton. When an aromatic ring of an aromatic compound having no nitrogen atom is efficiently reduced to become an anion state, the electron injecting zone obtains an excellent electron injection capability and is prevented from reacting with materials of adjacent luminescent zones.

Patent Literature 2 discloses a fluorescent organic EL device including an electron transporting layer that is provided by mixing a fused hydrocarbon compound having an anthracene skeleton or a tetracene skeleton with an organic metal complex containing an alkali metal such as lithium quinolinolate (Liq). The fused hydrocarbon compound has been known for having a longer lifetime than a lifetime of a typical device because of stability against oxidation and reduction.

Patent Literatures 3 and 4 disclose a technology of prolonging a lifetime of a fluorescent organic EL device by providing a phenanthroline derivative such as BCP (bathocuproine) and Bphen as a hole blocking layer between an emitting layer and an electron transporting layer. With this arrangement, holes leaking from the emitting layer to the electron transporting layer are blocked to prevent deterioration of the electron transporting layer that exhibits a low tolerance to holes.

Patent Literature 5 discloses a technology of preventing triplet excitons from diffusing into an electron transporting layer laminated adjacent to a hole blocking layer in a phosphorescent organic EL device and prolonging a lifetime thereof by using a fused hydrocarbon compound having large triplet energy as the hole blocking layer.

### CITATION LIST

### Patent Literatures

Patent Literature 1: Japanese Patent No. 3266573
Patent Literature 2: JP-A-2009-177128
Patent Literature 3: JP-A-10-79297
Patent Literature 4: JP-A-2002-100478
Patent Literature 5: JP-A-2009-147324

### Non-Patent Literature

Non-Patent Literature 1: D. Y. Kondakov, J. Appl. Phys., Vol. 102, p. 114504 (2007)

### SUMMARY OF THE INVENTION

### Problems to be Solved by the Invention

In Patent Literatures 1 and 2 disclosing the fluorescent organic EL device, the electron transporting material exhibiting small triplet energy, which is formed of the fused hydrocarbon compound having an anthracene skeleton or a tetracene skeleton, is used, so that effective improvement in luminous efficiency caused by a later-described TTF phenomenon (Triplet-Triplet Fusion phenomenon) is not achieved.

In Patent Literatures 3 and 4, the phenanthroline derivative such as BCP (bathocuproine) and Bphen is used as the hole blocking material. Since the phenanthroline derivative is vulnerable to holes, in other words, likely to be oxidized, the phenanthroline derivative exhibits poor hole tolerance and insufficient performance in terms of prolonging the lifetime of the device. Moreover, technology of improving luminous efficiency by inserting the hole blocking layer between the emitting layer and the electron transporting layer entails an increase in the number of layers in the multi-layered structure of the organic EL device. The increase in the number of layers in the multi-layered structure leads to process-up (i.e., increase in manufacturing steps) in manufacturing the organic EL device.

In Patent Literature 5, the fused hydrocarbon compound having large triplet energy is used for the hole blocking layer of the phosphorescent organic EL device. However, the electron injecting layer formed of a compound different from the fused hydrocarbon compound is provided between the cathode and the hole blocking layer, which leads to process-up in manufacturing the organic EL device.

An object of the invention is to provide a highly efficient and long-life organic EL device obtainable by a simple manufacturing process.

### Means for Solving the Problems

According to an aspect of the invention, an organic electroluminescence device includes an anode, an emitting layer, an electron transporting zone and a cathode in sequential order, in which a blocking layer is provided in the electron transporting zone adjacently to the emitting layer, the blocking layer contains a hydrocarbon compound having a fused ring (hereinafter, referred to as a fused hydrocarbon compound) and at least one compound selected from an electron-donating dopant and an organic metal complex containing an alkali metal, and triplet energy of the fused hydrocarbon compound is 2.0 eV or more.

According to another aspect of the invention, an organic electroluminescence device includes an anode, an emitting layer, an electron transporting zone and a cathode in sequential order, in which a blocking layer includes a first organic thin-film layer and a second organic thin-film layer that are sequentially laminated on the emitting layer, the first organic thin-film layer is formed of a fused hydrocarbon compound, the second organic thin-film layer includes the fused hydrocarbon compound and at least one compound selected from an electron-donating dopant and an organic metal complex containing an alkali metal, and triplet energy of the fused hydrocarbon compound is 2.0 eV or more.

In the above aspect of the invention, the electron-donating dopant is preferably at least one compound selected from an alkali metal, an alkaline earth metal, a rare-earth metal and an alkali metal compound.

In the above aspect of the invention, the alkali metal compound is preferably at least one compound selected from the group consisting of an alkali metal oxide, an alkali metal halide, an alkaline earth metal oxide, an alkaline earth metal halide, a rare earth metal oxide and a rare earth metal halide.

In the above aspect of the invention, the emitting layer preferably includes a host and a dopant that exhibits a fluorescent emission of a main peak wavelength of 550 nm or less.

In the above aspect of the invention, triplet energy (E^{T}_{d(F)}) of the dopant that exhibits a fluorescent emission is preferably larger than triplet energy (E^{T}ₕ) of the host.

In the above aspect of the invention, triplet energy of the fused hydrocarbon compound is preferably larger than triplet energy (E^{T}ₕ) of the host that exhibits a fluorescent emission.

In the above aspect of the invention, the emitting layer preferably contains a host and a dopant that exhibits a phosphorescent emission.

In the above aspect of the invention, triplet energy of the fused hydrocarbon compound is preferably larger than triplet energy (E^{T}_{d(P)}) of the dopant that exhibits a phosphorescent emission.

In the above aspect of the invention, the fused hydrocarbon compound is preferably represented by any one of formulae (1) to (4) as follows.

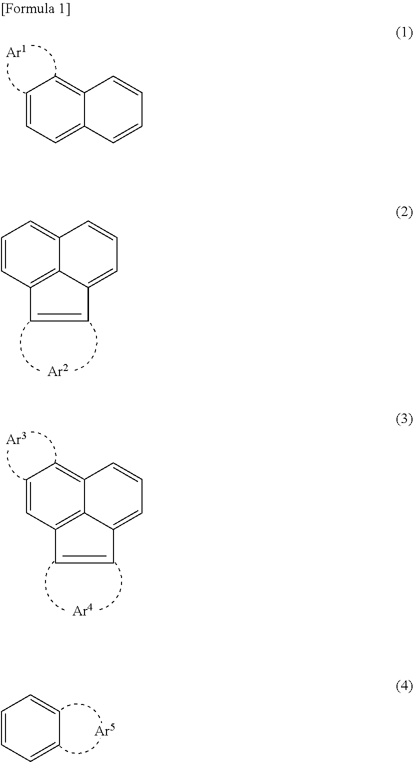

In formulae (1) to (4), Ar¹ to Ar⁵ each represent a substituted or unsubstituted fused ring structure having 4 to 16 ring carbon atoms.

In the above aspect of the invention, the organic metal complex containing an alkali metal is a compound represented by one of formulae (10) to (12) as follows.

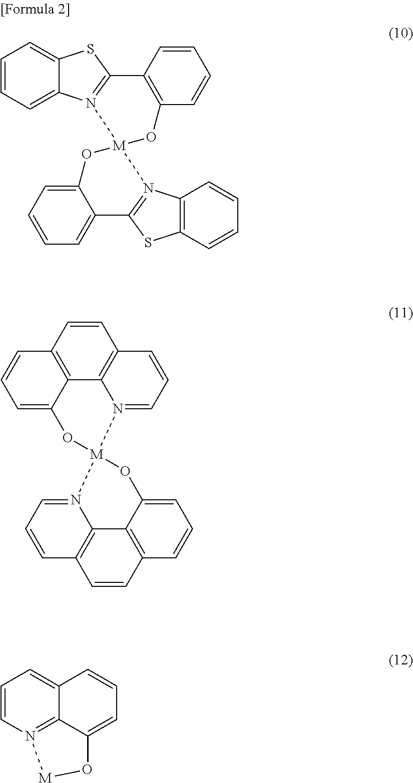

In the formulae (10) to (12), M represents an alkali metal atom.

In the above aspect of the invention, a layer formed of the at least one compound selected from the electron-donating dopant and the organic metal complex containing an alkali metal is preferably interposed between the blocking layer and the cathode.

In the above aspect of the invention, in the layer provided in the electron transporting zone and formed of the fused hydrocarbon compound and the at least one compound selected from the electron-donating dopant and the organic metal complex containing an alkali metal, the fused hydrocarbon compound and the at least one compound selected from the electron-donating dopant and the organic metal complex comprising an alkali metal are contained at a mass ratio in a range of 30:70 to 70:30.

According to the invention, a highly efficient and long-life organic EL device obtainable by a simple manufacturing process can be provided.

### BRIEF DESCRIPTION OF DRAWINGS

FIG. 1 shows an example of an organic electroluminescence device according to a first exemplary embodiment of the invention.

FIG. 2 is an illustration showing a relationship between triplet energy of an emitting layer and triplet energy of an electron transporting zone in the organic electroluminescence device according to the first exemplary embodiment.

FIG. 3 shows an example of an organic electroluminescence device according to a second exemplary embodiment of the invention.

FIG. 4 shows an example of an organic electroluminescence device according to a third exemplary embodiment of the invention.

FIG. 5 shows an example of an organic electroluminescence device according to a fourth exemplary embodiment of the invention.

FIG. 6 shows an example of an organic electroluminescence device according to a fifth exemplary embodiment of the invention.

FIG. 7 is an illustration showing a relationship between triplet energy of a third emitting layer and triplet energy of an electron transporting zone in the organic EL device according to the fifth exemplary embodiment.

FIG. 8 shows an example of an organic electroluminescence device according to a sixth exemplary embodiment of the invention.

### DESCRIPTION OF EXEMPLARY EMBODIMENTS

In organic EL devices of the invention, a fluorescent organic EL device can obtain a high luminous efficiency by using a TTF phenomenon. The TTF phenomenon used in the invention will be roughly described.

The behavior of triplet excitons generated within an organic substance has been hitherto theoretically examined. According to S. M. Bachilo et al. (J. Phys. Chem. A, 104, 7711 (2000)), assuming that high-order excitons such as quintet excitons are quickly returned to triplet excitons, triplet excitons (hereinafter abbreviated as 3A*) collide with one another with an increase in the density thereof, whereby a reaction shown by the following formula occurs. In the formula, 1A represents the ground state and 1A* represents the lowest singlet excitons.

³A*+³A*→(4/9)¹A+(1/9)¹A*+(13/9)³A*

In other words, 5³A*→4¹A+¹A*, and it is expected that, among triplet excitons initially generated, which account for 75%, one fifth thereof (i.e., 20%) is changed to singlet excitons. Accordingly, the amount of singlet excitons which contribute to emission is 40%, which is a value obtained by adding 15% (75%×(1/5)=15%) to 25%, which is the amount ratio of initially generated singlet excitons.

In other words, it can be seen that a fluorescent device having the internal quantum efficiency exceeding the theoretical limit 25% of the internal quantum efficiency of a typical fluorescent device is achievable by using emission of singlet excitons derived from triplet excitons. In the invention, a fluorescent organic EL device to effectively cause the above TTF phenomenon is provided.

It should be noted that the TTF phenomenon exerts the most significant effects on a blue fluorescent device among fluorescent organic EL devices. An electron transporting zone provided in the invention effectively causes a TTF phenomenon in a blue fluorescent device while functioning as an exciton blocking layer in a phosphorescent device. Accordingly, in an organic EL device having blue-, green- and red-emitting portions, the above electron transporting zone is commonly usable as an electron transporting zone in both an all-fluorescent organic EL device and a fluorescent-phosphorescent hybrid organic EL device.

Exemplary embodiments of the invention will be described below.

### First Exemplary Embodiment

### Arrangement of Organic EL Device

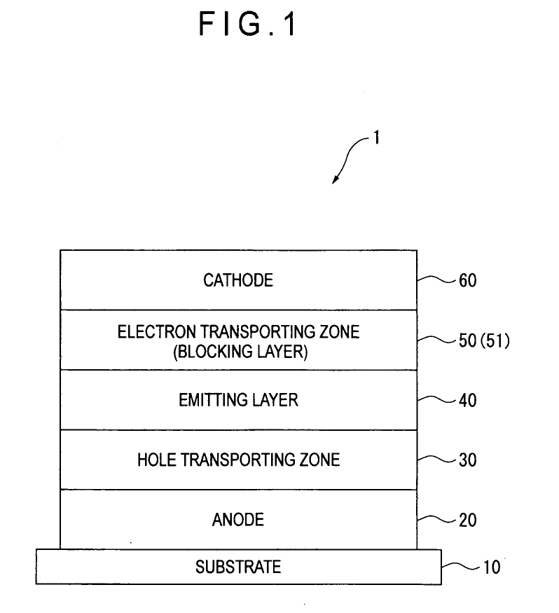

In an organic EL device 1 shown in FIG. 1, an anode 20, a hole transporting zone 30, an emitting layer 40, an electron transporting zone 50 and a cathode 60 are laminated on a substrate 10 in sequential order.

### Electron Transporting Zone/Blocking Layer

A blocking layer 51 is provided adjacently to the emitting layer 40 in the electron transporting zone 50. The blocking layer 51 has a function to prevent triplet excitons generated in the emitting layer 40 from energy-transferring into the electron transporting zone 50 and to trap the triplet excitons in the emitting layer 40, thereby increasing a density of the triplet excitons in the emitting layer 40 (described later).

The blocking layer 51 includes: a fused hydrocarbon compound; and at least one compound selected from an electron-donating dopant and an organic metal complex containing an alkali metal. The blocking layer 51 preferably includes at the mass ratio in a range of 30:70 to 70:30: the fused hydrocarbon compound; and at least one compound selected from the electron-donating dopant and the organic metal complex containing an alkali metal.

When a content of the fused hydrocarbon compound is less than the above ratio, the lifetime of the organic EL device is shortened. When a content of the electron-donating dopant or organic metal complex containing an alkali metal is less than the above ratio, drive voltage of the organic EL device is raised.

Specifically, the electron transporting zone of the first exemplary embodiment has the following functions as compared with a typical transporting layer:

(1) a function of electron injection from the cathode;

(2) a function of blocking triplet energy that causes a TTF phenomenon when the adjacent emitting layer is formed of a fluorescent device; and

(3) a function of preventing energy diffusion of phosphorescent emission when the adjacent emitting layer is formed of a phosphorescent device.

Moreover, since the electron transporting zone of the first exemplary embodiment is mainly formed of the fused hydrocarbon compound, the electron transporting zone is considered to exhibit higher tolerance and blocking function against holes entering through the emitting layer as compared with a device having an electron transporting layer formed of a nitrogen-containing cyclic compound.

When a layer is referred to as a blocking layer in the invention, the blocking layer means an organic layer having the functions (2) and (3) described above. The blocking layer functions differently from a hole blocking layer and a charge blocking layer.

The fused hydrocarbon compound contained in the blocking layer 51 has triplet energy (E^{T}ₑ) of 2.0 eV or more. When the fused hydrocarbon compound having triplet energy (E^{T}ₑ) of 2.0 eV or more is thus used in the blocking layer 51, triplet excitons generated in the emitting layer 40 can be appropriately prevented from energy-transferring into the electron transporting zone 50.

When the organic EL device 1 is, for instance, a blue fluorescent device using an anthracene derivative (triplet energy: about 1.8 eV) or a pyrene derivative (triplet energy: about 1.9 eV) which are the most effective host material in a blue fluorescent device, or when the organic EL device 1 is a red phosphorescent device using a compound that contains a phosphorescent dopant having triplet energy of less than 2.0 eV, energy transfer of triplet excitons is appropriately prevented for the following reason. For instance, since triplet energy of a typical red phosphorescent material is about 2.0 eV, energy transfer of triplet excitons can be effectively and appropriately prevented when a fused hydrocarbon compound having triplet energy of 2.0 eV or more is used in the blocking layer 51.

In the invention, triplet energy refers to a difference between energy in the lowest triplet state and energy in the ground state. The singlet energy (often referred to as energy gap) refers to a difference between energy in the lowest singlet state and energy in the ground state.

### Fused Hydrocarbon Compound

The fused hydrocarbon compound is preferably represented by one of formulae (1) to (4) as follows.

In the formulae (1) to (4), Ar¹ to Ar⁵ each represent a substituted or unsubstituted fused ring structure having 4 to 16 ring carbon atoms. Examples of Ar¹ to Ar⁵ are a phenanthrene ring, a benzophenanthrene ring, a dibenzophenanthrene ring, a chrysene ring, a benzochrysene ring, a dibenzochrysene ring, a fluoranthene ring, a benzofluoranthene ring, a triphenylene ring, a benzotriphenylene ring, a dibenzotriphenylene ring, a picene ring, a benzopicene ring and a dibenzopicene ring.

Examples of a substituent with which Ar¹ to Ar⁵ may be substituted are a halogen atom, an oxy group, an amino group, an alkoxy group, an aryloxy group, an alkoxycarbonyl group and a heterocyclic group.

The fused hydrocarbon compound, which does not contain a hetero atom in a fused ring, exhibits excellent tolerance to oxidation and reduction as compared with an electron transporting material containing a hetero atom (e.g. a typical phenanthroline derivative). Accordingly, a lifetime of the organic EL device 1 can be prolonged.

### Electron-Donating Dopant

An electron-donating dopant is at least one compound selected from the group consisting of an alkali metal, an alkaline earth metal, a rare earth metal, an alkali metal oxide, an alkali metal halide, an alkaline earth metal oxide, an alkaline earth metal halide, a rare earth metal oxide and a rare earth metal halide

Examples of the alkali metal are Li (lithium, work function: 2.93 eV), Na (sodium, work function: 2.36 eV), K (potassium, work function: 2.3 eV), Rb (rubidium, work function: 2.16 eV), and Cs (cesium, work function: 1.95 eV). The values of the work function in parentheses are described in Kagaku Binran (Basic II, p. 493, in 1984 by the Chemical Society of Japan). The same applies to the following.

Preferable examples of the alkaline earth metal are Ca (calcium, work function: 2.9 eV), Mg (magnesium, work function: 3.66 eV), Ba (barium, work function: 2.52 eV) and Sr (strontium, work function: 2.0 to 2.5 eV). The value of the work function of strontium is described in Physics of Semiconductor Devices (N.Y. Wiley, in 1969, p. 366).

Preferable examples of the rare earth metal are Yb (ytterbium, work function: 2.6 eV), Eu (europium, work function: 2.5 eV), Gd (gadolinium, work function: 3.1 eV) and En (erbium, work function: 2.5 eV).

Examples of the alkali metal oxide are Li₂O, LiO and NaO.

Preferable examples of the alkaline earth metal oxide are CaO, BaO, SrO, BeO and MgO.

Examples of the alkali metal halide are fluorides such as LiF, NaF, CsF and KF and chlorides such as LiCl, KCl and NaCl.

Preferable examples of the alkaline earth metal halide are fluorides such as CaF₂, BaF₂, SrF₂, MgF₂ and BeF₂, and halides other than the fluorides.

### Organic Metal Complex Containing Alkali Metal

An organic metal complex containing an alkali metal is preferably a compound represented by one of formulae (10) to (12) as follows.

In the formulae (10) to (12), M represents an alkali metal atom. Examples of the alkali metal are the same as those described in relation to the electron-donating dopant.

Because the fused hydrocarbon compound has no electron injection capability, electrons are not injected from the cathode 60 to the electron transporting zone 50 when only the fused hydrocarbon compound is used for the electron transporting zone 50.

In contrast, since the blocking layer 51 contains the fused hydrocarbon compound and at least one compound selected from the electron-donating dopant and the organic metal complex containing the alkali metal, electrons are injectable from the cathode 60 to the electron transporting zone 50.

Further, a manufacturing process can be simplified since an electron transporting layer formed of a different material is not required between the electron transporting zone 50 and the cathode.

### Emitting Layer

The emitting layer 40 includes a host and a dopant. The dopant is selected from a dopant generating fluorescent emission and a dopant generating phosphorescent emission.

### Fluorescent Dopant

The dopant generating fluorescent emission (hereinafter, occasionally referred to as a “fluorescent dopant”) preferably has a main peak wavelength of 550 nm or less. The main peak wavelength in the invention means a peak wavelength of an emission spectrum exhibiting the maximum luminous intensity among emission spectra measured in a toluene solution with a concentration of the fluorescent dopant from 10⁻⁵ mol/L to 10⁻⁶ mol/L.

The fluorescent dopant is selected from a fluoranthene derivative, pyrene derivative, aryl acethylene derivative, fluorene derivative, boron complex, oxadiazole derivative and anthracene derivative. The fluorescent dopant is preferably selected from a fluoranthene derivative, pyrene derivative and boron complex, more preferably from a fluoranthene derivative and boron complex.

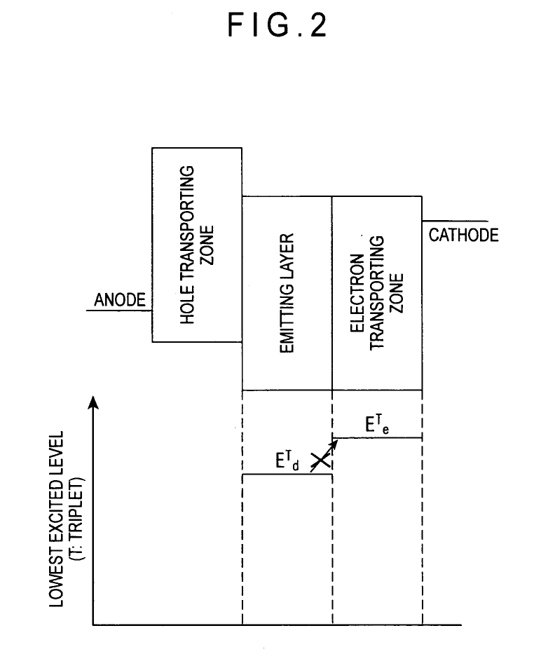

When the emitting layer 40 contains a host and a fluorescent dopant, holes injected from the anode 20 are injected into the emitting layer 40 through the hole transporting zone 30 in FIG. 2. Electrons injected from the cathode 60 are injected into the emitting layer 40 through the electron transporting zone 50. Each time the holes and the electrons are injected to the emitting layer 40, the holes and the electrons are recombined in the emitting layer 40 to generate singlet excitons and triplet excitons. There are two manners as for the occurrence of recombination: recombination may occur either on host molecules or on dopant molecules. In this exemplary embodiment, triplet energy E^{T}_{d(F)} of the fluorescent dopant is preferably larger than triplet energy E^{T}ₕ of the host.

When the relationship that E^{T}_{d(F)} is larger than E^{T}ₕ is satisfied, triplet excitons generated by recombination on the host do not energy-transfer to the dopant having a higher triplet energy. Triplet excitons generated by recombination on dopant molecules quickly energy-transfer to host molecules. In other words, the triplet excitons on the host do not transfer to the dopant and efficiently collide with one another on the host by the TTF phenomenon, thereby generating singlet excitons.

Further, when the emitting layer 40 is arranged such that singlet energy E^{S}_{d} of the fluorescent dopant is smaller than singlet energy E^{S}ₕ of the host, the singlet excitons generated by the TTF phenomenon energy-transfer from the host to the dopant, thereby contributing to fluorescent emission of the dopant. In dopants which are usually used in a fluorescent device, transition from the triplet state to the ground state should be inhibited. In such a transition, triplet excitons are not optically energy-deactivated, but are thermally energy-deactivated. However, when the relation between the triplet energy of the host and the triplet energy of the dopant is satisfied as described above, the singlet excitons are efficiently generated by the collision of the triplet excitons before they are thermally deactivated, thereby improving luminous efficiency.

Moreover, since triplet energy E^{T}ₑ of the fused hydrocarbon compound contained in the blocking layer 51 is 2.0 eV or more as described above, energy is not transferred to the electron transporting zone 50, so that the triplet excitons are trapped in the emitting layer 40 to increase a density of the triplet excitons in the emitting layer 40.

In order to efficiently trap the triplet excitons in the emitting layer 40, it is preferable that the triplet energy E^{T}ₑ of the fused hydrocarbon compound is larger than the triplet energy E^{T}ₕ of the host and the triplet energy E^{T}ₑ of the fused hydrocarbon compound is larger than the triplet energy E^{T}_{d(F)} of the fluorescent dopant.

Since the relations of triplet energy between the components of the emitting layer 40 and the blocking layer 51 are defined as described above, the density of triplet excitons in the emitting layer 40 is increased, so that triplet excitons of the host efficiently become singlet excitons in the emitting layer 40. The singlet excitons are transferred to the dopant and optically energy-deactivated, thereby improving luminous efficiency.

### Fluorescent Host

When the host and the fluorescent dopant form the emitting layer 40, the host can be selected from, for instance, compounds described in JP-A-2010-50227 and the like. The host is an anthracene derivative and a polycyclic aromatic skeleton-containing compound, preferably an anthracene derivative.

### Phosphorescent Host

When the host and the phosphorescent dopant form the emitting layer 40, the host is exemplified by a fused aromatic ring derivative and a heterocyclic compound. As the fused aromatic ring derivative, a phenanthrene derivative and a fluoranthene derivative are more preferable in view of luminous efficiency and emission lifetime.

Examples of the heterocyclic compound are a carbazole derivative, dibenzofuran derivative, ladder-type furan compound and pyrimidine derivative.

The phosphorescent host may also be formed of a material selected from a fluorene-containing aromatic compound described in Japanese Patent Application No. 2009-239786, an indolocarbazole compound described in International Publication No. 08/056,746 and a zinc complex described in JP-A-2005-11610.

### Phosphorescent Dopant

The dopant generating phosphorescent emission (hereinafter, occasionally referred to as a “phosphorescent dopant”) preferably contains a metal complex. The metal complex preferably includes: a metal atom selected from iridium (Ir), platinum (Pt), osmium (Os), gold (Au), rhenium (Re) and ruthenium (Ru); and a ligand. Particularly, the ligand and the metal atom preferably form an ortho-metal bond.

The phosphorescent-emitting material is preferably a compound containing a metal selected from iridium (Ir), osmium (Os) and platinum (Pt) because such a compound, which exhibits high phosphorescence quantum yield, can further enhance external quantum efficiency of the emitting device. The phosphorescent-emitting material is more preferably a metal complex such as an iridium complex, osmium complex or platinum complex, among which an iridium complex and platinum complex are more preferable and ortho metalation of an iridium complex is the most preferable. The organic metal complex formed of the ligand selected from the group consisting of phenyl quinoline, phenyl isoquinoline, phenyl pyridine, phenyl pyrimidine and phenyl imidazoles is preferable in terms of luminous efficiency and the like.

Also when the emitting layer 40 contains a host and a phosphorescent dopant, as described above in FIG. 2, holes injected from the anode 20 are injected into the emitting layer 40 through the hole transporting zone 30 and the holes and the electrons are recombined in the emitting layer 40 to generate singlet excitons and triplet excitons. There are two manners as for the occurrence of recombination: recombination may occur either on host molecules or on dopant molecules. In the phosphorescent device, triplet energy E^{T}ₕ of the host is preferably larger than triplet energy E^{T}_{d(P)} of the phosphorescent dopant.

When the relationship that E^{T}ₕ is larger than E^{T}_{d(P)} is satisfied, triplet excitons generated by recombination on the host molecules quickly energy-transfer to the dopant. Triplet excitons generated by recombination on the dopant molecules do not energy-transfer to the host. Thus, the triplet excitons contribute to phosphorescent emission of the dopant.

Moreover, since the triplet energy E^{T}ₑ of the fused hydrocarbon compound contained in the blocking layer 51 is 2.0 eV or more as described above, energy is not transferred to the electron transporting zone 50, so that the triplet excitons are trapped in the emitting layer 40 to increase a density of the triplet excitons in the emitting layer 40.

In order to efficiently trap the triplet excitons in the emitting layer 40, the triplet energy E^{T}ₑ of the fused hydrocarbon compound is preferably larger than the triplet energy E^{T}_{d(P)} of the phosphorescent dopant.

Since the relations in triplet energy between the components of the emitting layer 40 and the blocking layer 51 are defined as described above, the density of triplet excitons in the emitting layer 40 is increased and the triplet excitons are optically energy-deactivated on the dopant, thereby improving luminous efficiency.

Examples of the phosphorescent dopant are shown below, but the phosphorescent dopant is not limited to the following.

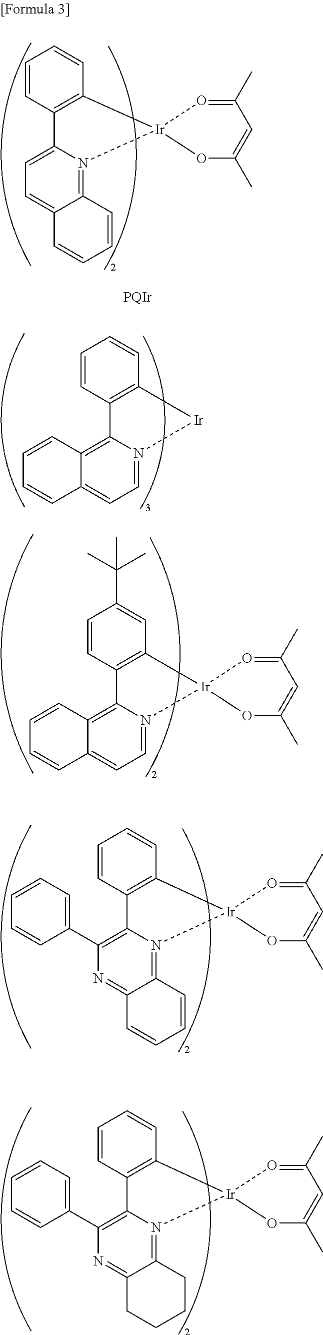

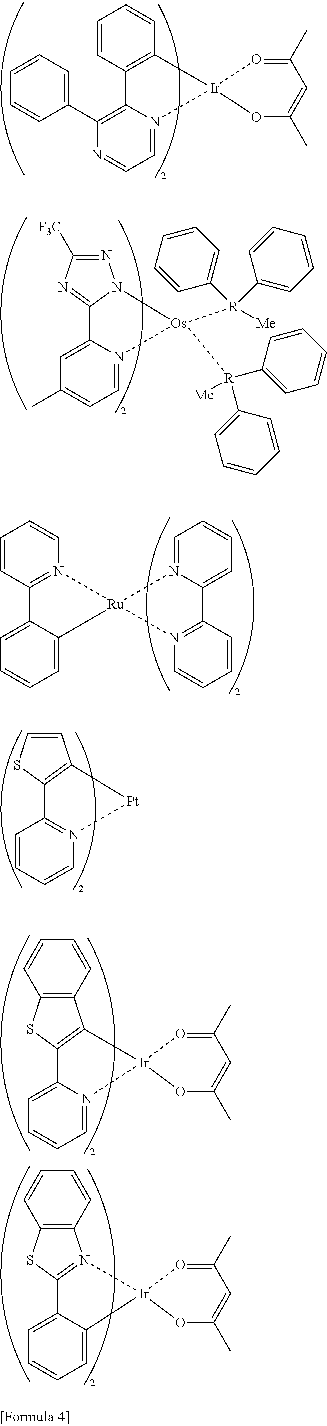

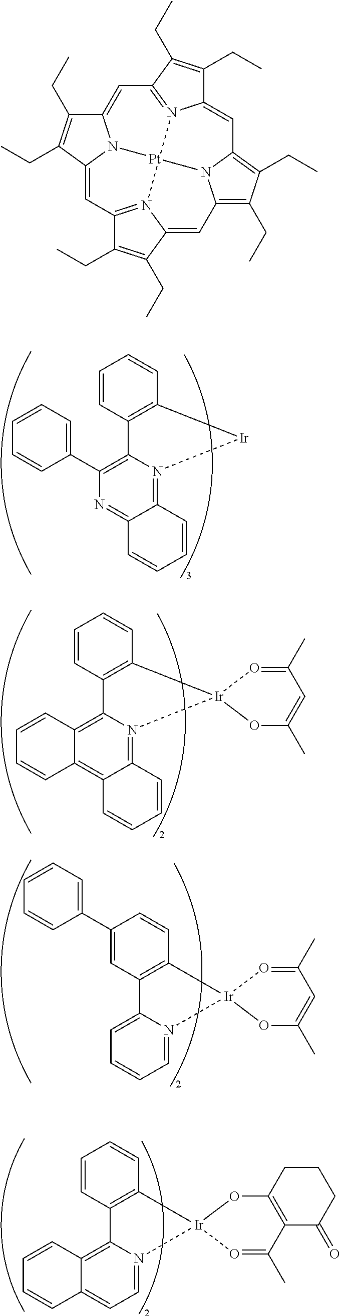

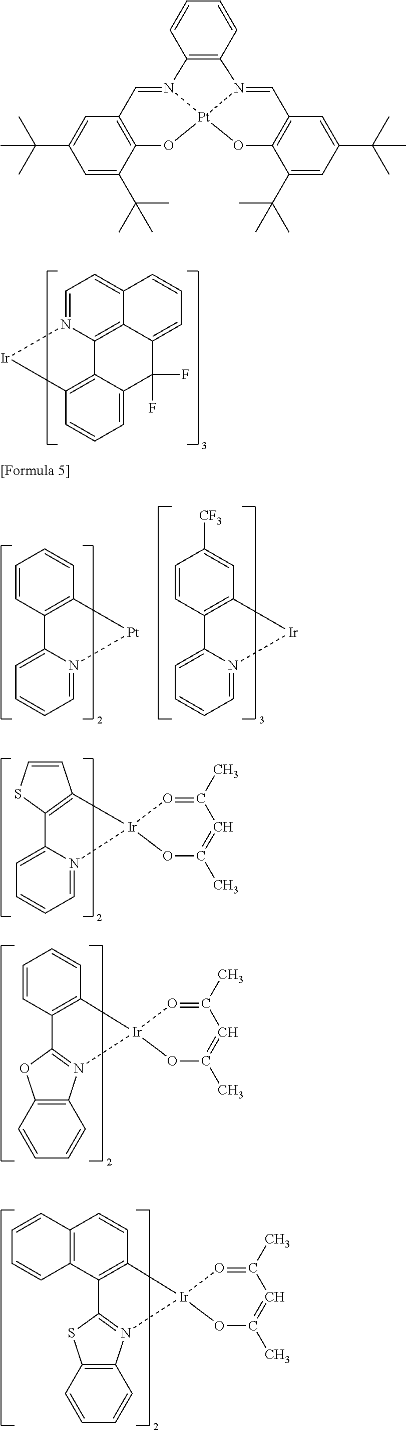

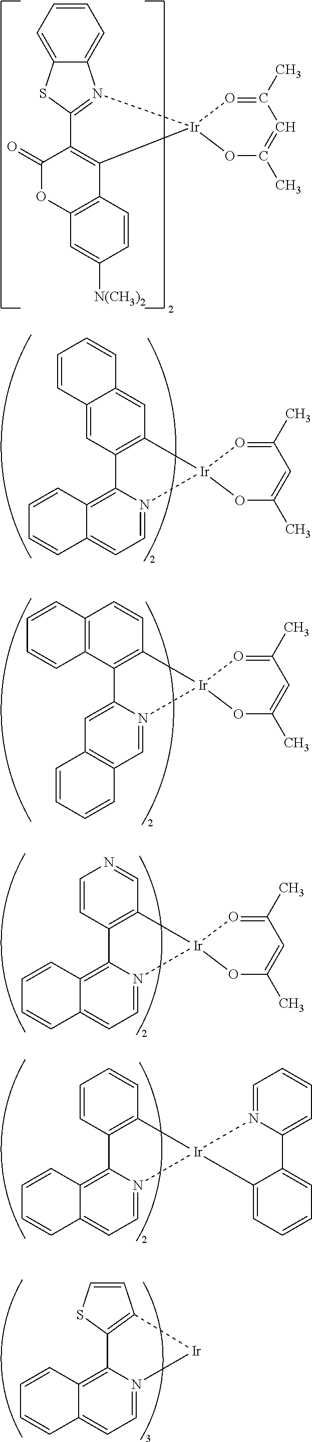

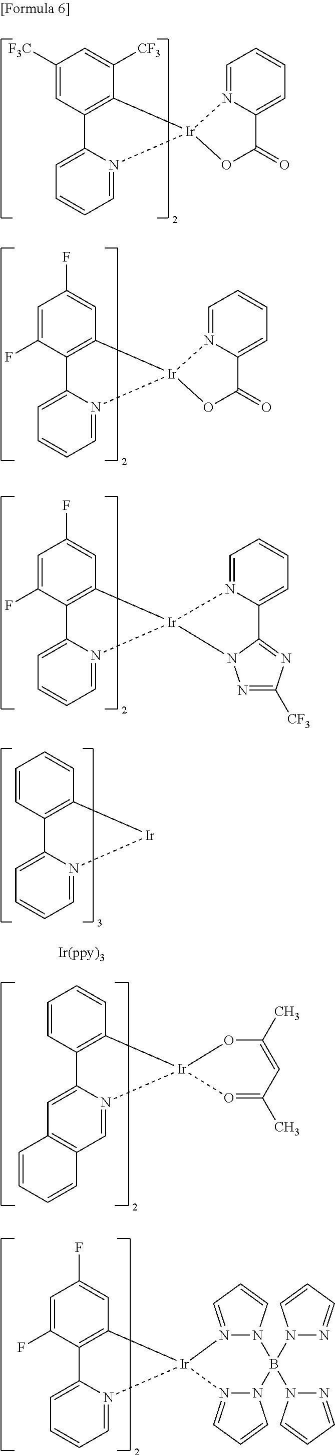

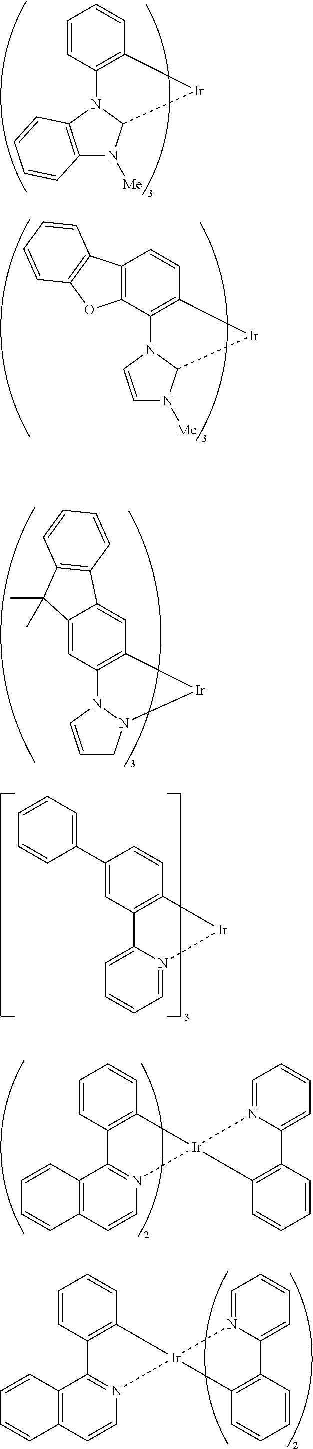

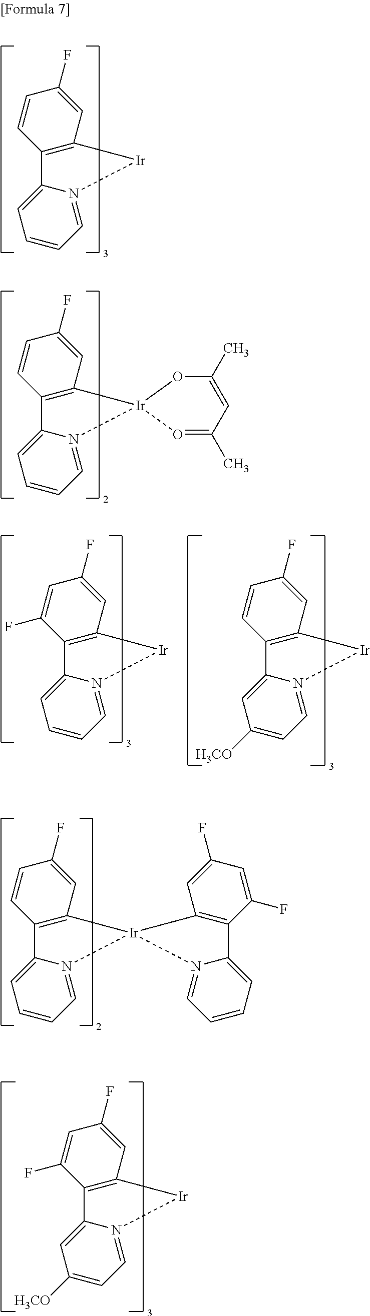

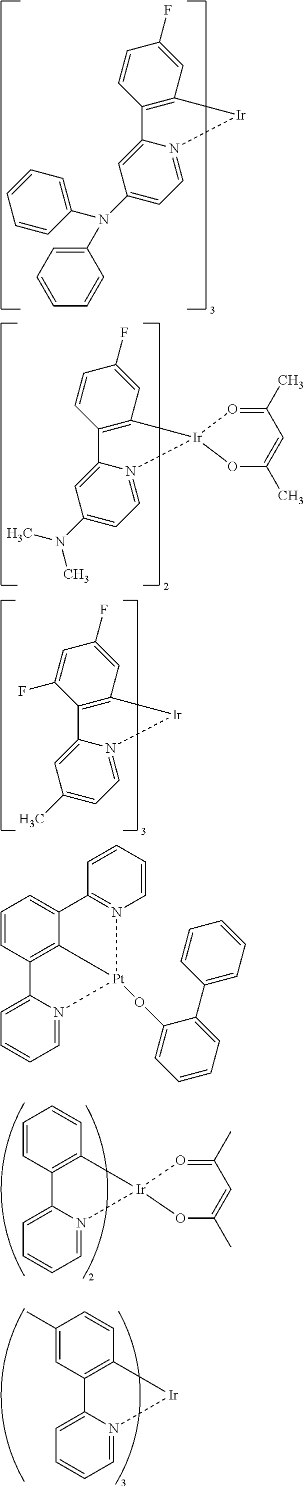

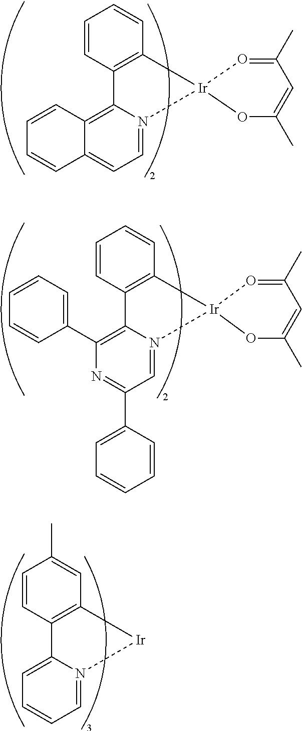

### Substrate

The substrate 10 supports the anode 20, the hole transporting zone 30, the emitting layer 40, the electron transporting zone 50 and the cathode 60. The substrate is preferably a smooth substrate that transmits 50% or more of light in a visible region of 400 nm to 700 nm.

The substrate 10 is exemplarily a glass plate, a polymer plate or the like.

For the glass plate, materials such as soda-lime glass, barium/strontium-containing glass, lead glass, aluminosilicate glass, borosilicate glass, barium borosilicate glass and quartz can be used.

For the polymer plate, materials such as polycarbonate, acryl, polyethylene terephthalate, polyether sulfide and polysulfone can be used.

### Anode and Cathode

The anode 20 of the organic EL device 1 serves for injecting holes into the hole transporting zone 30 or the emitting layer 40. It is effective that the anode 20 has a work function of 4.5 eV or more.

Exemplary materials for the anode are alloys of indium-tin oxide (ITO), tin oxide (NESA), indium zinc oxide, gold, silver, platinum and copper.

The anode 20 can be manufactured by forming a thin film from these anode materials, for instance, on the substrate 10 through methods such as vapor deposition and sputtering.

When light from the emitting layer 40 is to be emitted through the anode 20 as in this exemplary embodiment, the anode 20 preferably transmits more than 10% of the light in the visible region. Sheet resistance of the anode 20 is preferably several hundreds Ω/sq. or lower. Although depending on the material of the anode 20, a thickness of the anode 20 is typically in a range from 10 nm to 1 μm, preferably in a range from 10 nm to 200 nm.

The cathode 60 is preferably formed of a material with a smaller work function in order to inject electrons into the electron transporting zone 50.

Although a material for the cathode is subject to no specific limitation, examples of the material are indium, aluminum, magnesium, alloy of magnesium and indium, alloy of magnesium and aluminum, alloy of aluminum and lithium, alloy of aluminum, scandium and lithium, and alloy of magnesium and silver.

Like the anode 20, the cathode 60 may also be made by forming a thin film, for instance, on the electron transporting zone 50 through a method such as vapor deposition or sputtering. In addition, light from the emitting layer 40 may be adapted to be emitted through the cathode 60. When light from the emitting layer 40 is to be emitted through the cathode 60, the cathode 60 preferably transmits more than 10% of the light in the visible region.

Sheet resistance of the cathode is preferably several hundreds Ω/sq. or lower.

Although depending on the material of the cathode, a thickness of the cathode is typically in a range from 10 nm to 1 μm, preferably in a range from 50 nm to 200 nm.

### Hole Transporting Zone

The hole transporting zone 30 is provided between the emitting layer 40 and the anode 20 for aiding the injection of holes into the emitting layer 40 and transporting the holes to the emitting region. The hole transporting zone 30 may be formed by, for instance, a hole injecting layer or a hole transporting layer. The hole injecting layer and the hole transporting layer may form a laminate.

The hole injecting layer or the hole transporting layer (including the hole injecting/transporting layer) may contain an aromatic amine compound such as an aromatic amine derivative represented by the following formula (I).

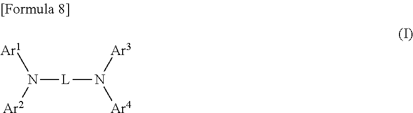

In the formula (I), Ar¹ to Ar⁴ represent an aromatic hydrocarbon group having 6 to 50 ring carbon atoms (which may have a substituent), a fused aromatic hydrocarbon group having 6 to 50 ring carbon atoms (which may have a substituent), an aromatic heterocyclic group having 2 to 40 ring carbon atoms (which may have a substituent), a fused aromatic heterocyclic group having 2 to 40 ring carbon atoms (which may have a substituent), a group provided by bonding the aromatic hydrocarbon group and the aromatic heterocyclic group, a group provided by bonding the aromatic hydrocarbon group and the fused aromatic heterocyclic group, a group provided by bonding the fused aromatic hydrocarbon group and the aromatic heterocyclic group, or a group provided by bonding the fused aromatic hydrocarbon group and the fused aromatic heterocyclic group.

Aromatic amine represented by the following (II) can also be preferably used for forming the hole injecting layer or the hole transporting layer.

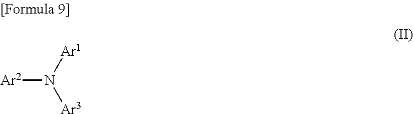

In the formula (II), Ar¹ to Ar⁴ each represent the same as Ar¹ to Ar⁴ of the above (I).

### Layer Thickness

In the organic EL device 1, a thickness of each of the emitting layer and the like between the anode 20 and the cathode 60 is not particularly limited except for a thickness of each of the above-mentioned layers to be particularly defined. However, the thickness of each of the emitting layer and the like is typically preferably in a range from several nanometers to 1 μM because an excessively-thinned film is likely to entail defects such as a pin hole while an excessively-thickened film requires application of high voltage and deteriorates efficiency.

### Manufacturing Method of Organic EL Device

A manufacturing method of the organic EL device 1 is subject to no limitation. Any typical manufacturing methods used for an organic EL device are usable for manufacturing the organic EL device 1. Specifically, each layer is formable by a vacuum deposition method, a casting method, a coating method, a spin coating method or the like.

Moreover, in addition to the casting method, the coating method and the spin coating using a solution, in which the organic material of the layers are dispersed, on a transparent polymer such as polycarbonate, polyurethane, polystyrene, polyarylate and polyester, the respective layers can be formed by simultaneous deposition with the organic material and the transparent polymer.

### Second Exemplary Embodiment

Next, a second exemplary embodiment of the invention will be described.

In the description of the second exemplary embodiment, the same components as those in the first exemplary embodiment will be denoted by the same reference numerals to simplify or omit description of the components. The fused hydrocarbon compound, the electron-donating dopant, the organic metal complex including an alkali metal and other compounds used in the second exemplary embodiment are the same compounds described in the first exemplary embodiment.

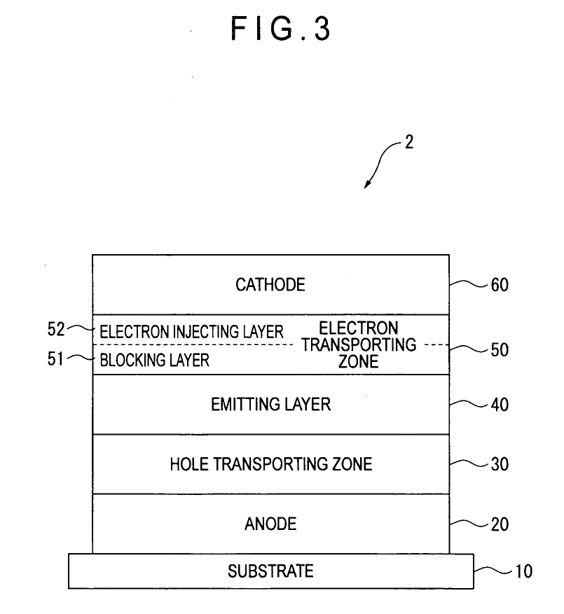

In an organic EL device 2 according to the second exemplary embodiment, as shown in FIG. 3, a layer (an electron injecting layer) 52 is formed in the electron transporting zone 50 and between the blocking layer 51 and the cathode 60, the layer 52 being formed by at least one compound selected from the electron-donating dopant and the organic metal complex including an alkali metal. The electron injecting layer 52 does not contain the fused hydrocarbon compound.

In the second exemplary embodiment, the compound (hereinafter, referred to as an electron-injecting-layer compound in the second exemplary embodiment) including at least one compound selected from the electron-donating dopant and the organic metal complex including an alkali metal is present at the interface between the electron transporting zone 50 and the cathode 60. In other words, since contact area between the cathode 60 and the electron-injecting-layer compound is enlarged, electron injecting capability from the cathode 60 to the electron transporting zone 50 is improved, resulting in lowering drive voltage Since the fused hydrocarbon compound has no electron injecting capability to inject electrons from the cathode 60 to the electron transporting zone 50, the electron injecting layer 52 provided at the interface with the cathode 60 is highly advantageous for improving the electron injecting capability.

Also in the organic EL device 2 according to the second exemplary embodiment, a manufacturing process can be simplified since an electron transporting layer formed of a different material is not required between the electron transporting zone 50 and the cathode 60. Since the electron-injecting-layer compound is obtainable by using at least one compound for the blocking layer 51 selected from the electron-donating dopant and the organic metal complex including an alkali metal, for instance, after formation of the blocking layer 51 by a vacuum deposition method (co-evaporation), the electron injecting layer 52 is formable by stopping evaporation of only the fused hydrocarbon compound while continuing evaporation of the electron-injecting-layer compound. Accordingly, the organic EL device 2 can be manufactured by a simple process.

Specifically, the electron transporting zone of the second exemplary embodiment can reinforce the following function as compared with that of the first exemplary embodiment:

(1) a function of electron injection from the cathode.

A thickness of the electron injecting layer 52 in the second exemplary embodiment is preferably in a range of 0.5 nm to 3 nm. The electron-donating dopant or the metal complex including an alkali metal has a function of electron injection, but exhibits a low electron mobility. Accordingly, when the thickness exceeds 3 nm, drive voltage is increased.

The blocking layer 51 of the second exemplary embodiment preferably includes at a mass ratio in a range of 30:70 to 70:30: a fused hydrocarbon compound; and at least one compound selected from an electron-donating dopant and an organic metal complex containing an alkali metal.

When a content of the fused hydrocarbon compound is less than the above ratio, the lifetime of the organic EL device is shortened. When a content of the electron-donating dopant or organic metal complex containing an alkali metal is less than the above ratio, drive voltage of the organic EL device is raised.

### Third Exemplary Embodiment

Next, a third exemplary embodiment of the invention will be described.

In the description of the third exemplary embodiment, the same components as those in the first exemplary embodiment are denoted by the same reference numerals to simplify or omit description of the components. The fused hydrocarbon compound, the electron-donating dopant, the organic metal complex including an alkali metal and other compounds used in the third exemplary embodiment are the same compounds described in the first exemplary embodiment.

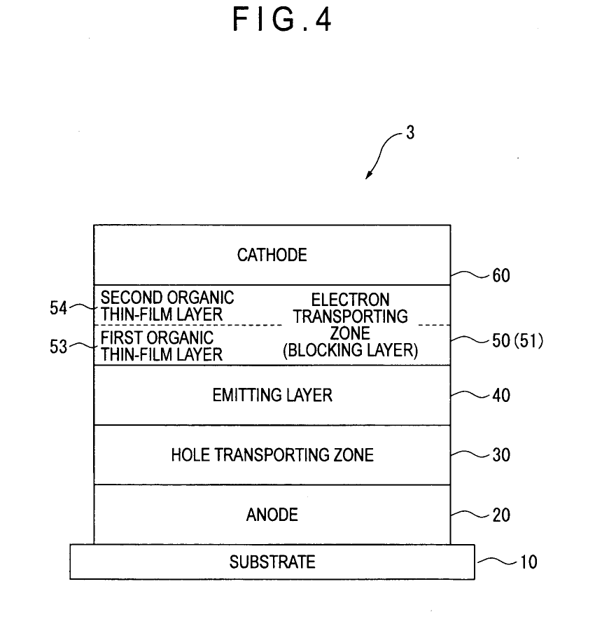

An organic EL device 3 according to the third exemplary embodiment, as shown in FIG. 4, is provided with the blocking layer 51 in the electron transporting zone 50 in the same manner as in the first exemplary embodiment and includes a first organic thin-film layer 53 and a second organic thin-film layer 54 which are sequentially laminated on the emitting layer 40.

The first organic thin-film layer 53 is formed of the fused hydrocarbon compound and includes neither electron-donating dopant nor organic metal complex including an alkali metal.

The second organic thin-film layer 54 includes: the fused hydrocarbon compound; and at least one compound selected from the electron-donating dopant and the organic metal complex containing an alkali metal.

In the third exemplary embodiment, the first organic thin-film layer 53 formed of the fused hydrocarbon compound is present at the interface between the electron transporting zone 50 and the emitting layer 40. In other words, direct contact between the emitting layer 40 and the electron-donating dopant or the organic metal complex containing an alkali metal is avoided.

The electron-donating dopant or the organic metal complex containing an alkali metal may be optically deactivated by accepting triplet energy transfer from the emitting layer 40. In view of the above, the first organic thin-film layer 53 is provided between the emitting layer 40 and the second organic thin-film layer 54, thereby avoiding direct contact between the emitting layer 40 and the electron-donating dopant or the organic metal complex containing an alkali metal. As a result, the electron-donating dopant or the organic metal complex containing an alkali metal can emit light without being optically deactivated, so that decrease in the luminous efficiency of the device can be prevented.

Also in the organic EL device 3 of the third exemplary embodiment, an electron transporting layer or the like formed of a different material is not required between the electron transporting zone 50 and the cathode and a common fused hydrocarbon compound is usable in the first and second organic thin-film layers 53 and 54. As a result, a manufacturing process of the organic EL device 3 can be simplified.

Specifically, the electron transporting zone of the third exemplary embodiment can reinforce the following functions as compared with that of the first exemplary embodiment:

(2) a function of blocking triplet energy for expressing a TTF phenomenon when the adjacent emitting layer is formed of a fluorescent device; and

(3) a function of preventing energy diffusion of phosphorescent emission when the adjacent emitting layer is formed of a phosphorescent device.

The second organic thin-film layer 54 preferably includes at a mass ratio in a range of 30:70 to 70:30: a fused hydrocarbon compound; and at least one compound selected from an electron-donating dopant and an organic metal complex containing an alkali metal.

When a content of the fused hydrocarbon compound is less than the ratio, lifetime of the organic EL device is shortened. When a content of the electron-donating dopant or organic metal complex containing an alkali metal is less than the ratio, drive voltage of the organic EL device is raised.

### Fourth Exemplary Embodiment

Next, a fourth exemplary embodiment of the invention will be described.

In the description of the fourth exemplary embodiment, the same components as those in the first to third exemplary embodiments are denoted by the same reference numerals to simplify or omit description of the components. The fused hydrocarbon compound, the electron-donating dopant, the organic metal complex including an alkali metal and other compounds used in the fourth exemplary embodiment are the same compounds described in the first exemplary embodiment.

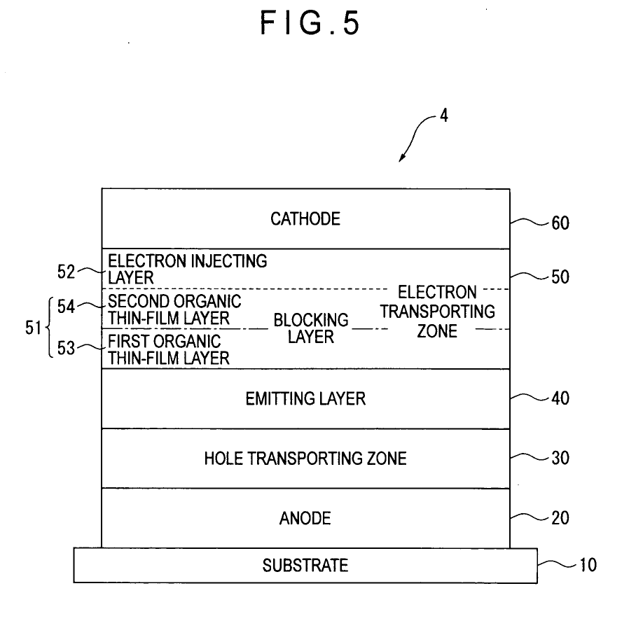

As shown in FIG. 5, an organic EL device 4 according to the fourth exemplary embodiment includes the blocking layer 51 and the electron injecting layer 52 in the electron transporting zone 50 in sequential order from the emitting layer 40. The electron injecting layer 52 is the same as that described in the second exemplary embodiment.

The blocking layer 51 according to the fourth exemplary embodiment includes the first and second organic thin-film layers 53 and 54 that are sequentially laminated on the emitting layer 40 in the same manner as the blocking layer 51 according to the third exemplary embodiment.

Specifically, the electron transporting zone of the fourth exemplary embodiment can reinforce the following functions as compared with those of the first to third exemplary embodiments:

(1) a function of electron injection from the cathode;

(2) a function of blocking triplet energy for expressing a TTF phenomenon when the adjacent emitting layer is formed of a fluorescent device; and

(3) a function of preventing energy diffusion of phosphorescent emission when the adjacent emitting layer is formed of a phosphorescent device.

### Fifth Exemplary Embodiment

Next, a fifth exemplary embodiment of the invention will be described.

In the description of the fifth exemplary embodiment, the same components as those in the first to third exemplary embodiments are denoted by the same reference numerals to simplify or omit description of the components. The fused hydrocarbon compound, the electron-donating dopant, the organic metal complex including an alkali metal and other compounds used in the fifth exemplary embodiment are the same compounds described in the first exemplary embodiment.

An organic electroluminescence device according to the fifth exemplary embodiment includes an anode, a plurality of emitting layers, an electron transporting zone and a cathode in sequential order. The electron transporting zone is as described above. A charge blocking layer is provided between any two layers of the plurality of emitting layers. The blocking layer in the electron transporting zone and the emitting layer adjacent to the blocking layer satisfy the relationship described in the first exemplary embodiment.

As a preferable arrangement of the organic EL device according to the fifth exemplary embodiment, the anode, the first emitting layer, the charge blocking layer, the second emitting layer and the cathode are sequentially laminated as described in, for instance, Japanese Patent No. 4134280, the specification of US 2007/0273270, and the specification of WO 2008/023623. This arrangement includes the electron transporting zone including the blocking layer between the second emitting layer and the cathode for preventing triplet excitons from diffusing. Here, the charge blocking layer provided between the first and second emitting layers is a layer that includes energy barriers of a HOMO level and a LUMO level against the adjacent emitting layers, thereby controlling carrier injection to the adjacent emitting layers and the carrier balance between electrons and holes injected in the emitting layers.

Specific examples of such an arrangement are given below.

anode/first emitting layer/charge blocking layer/second emitting layer/electron transporting zone/cathode

anode/first emitting layer/charge blocking layer/second emitting layer/third emitting layer/electron transporting zone/cathode

It is preferred that a hole transporting zone is provided between the anode and the first emitting layer in the same manner as in other exemplary embodiments.

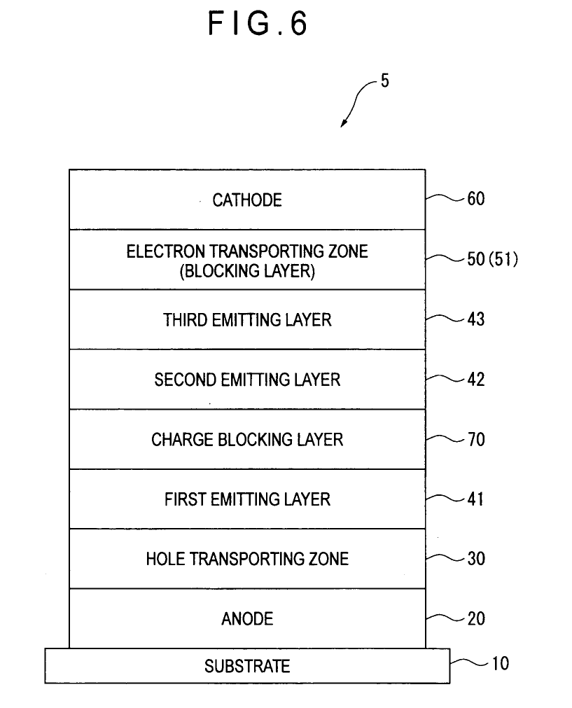

FIG. 6 schematically shows an arrangement of the organic EL device 5 according to the fifth exemplary embodiment. The organic EL device 5 is different from the organic EL device 1 according to the first exemplary embodiment in that a first emitting layer 41, a second emitting layer 42 and a third emitting layer 43 are provided in sequential order from the anode 20 and a charge blocking layer 70 is provided between the first and second emitting layers 41 and 42. In the organic EL device 5, the third emitting layer 43 and the blocking layer 51 in the electron transporting zone 50 satisfy the relationship described in the first exemplary embodiment. As a result, the organic EL device 5 can also exhibit the functions (1) to (3) of the electron transporting zone as described in the first exemplary embodiment.

The first, second and third emitting layers 41, 42 and 43 may provide fluorescent emission or phosphorescent emission.

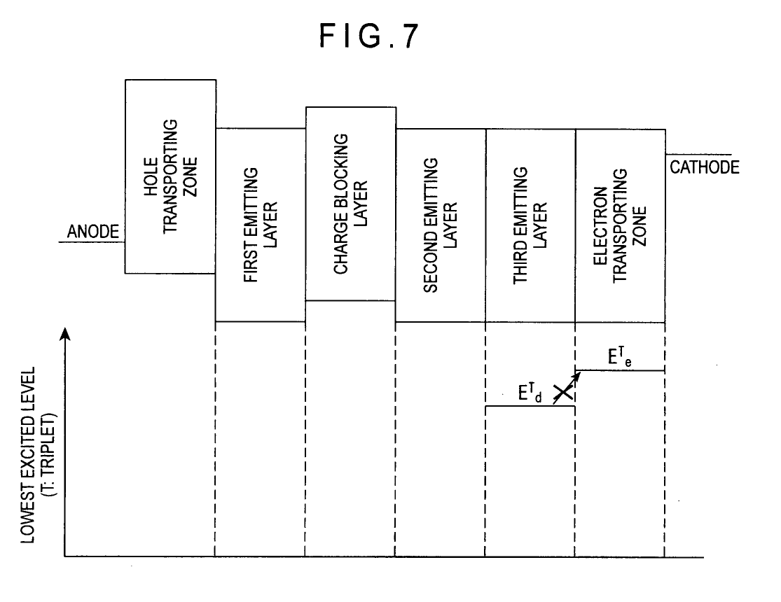

HOMO and LUMO energy levels of each layer of the organic EL device 5 according to the fifth exemplary embodiment are shown in an upper part of FIG. 7. A relationship of energy gap between the third emitting layer 43 and the blocking layer 51 of the electron transporting zone 50 is shown in a lower part of FIG. 7.

The device of the fifth exemplary embodiment is suitable as a white emitting device. The device adjusts the emission colors of the first, second and third emitting layers 41, 42 and 43, thereby provide white emission. Alternatively, the device may only include the first and second emitting layers 41 and 42 and provide white emission by adjusting emission colors of these two emitting layers.

Moreover, with an arrangement in which the first emitting layer 41 includes a hole transporting material as a host and the fluorescent dopant having a main peak wavelength of larger than 550 nm, and the second emitting layer 42 (and the third emitting layer 43) includes an electron transporting material as a host and the fluorescent dopant having a main peak wavelength of 550 nm or less, the device of the fifth exemplary embodiment can provide a white emitting device that exhibits a higher luminous efficiency than conventional white emitting devices, even though all the materials are fluorescent materials.

Reference is made particularly to the hole transporting zone 30 adjacent to the emitting layer. In order to allow the TTF phenomenon to occur effectively, it is preferred that the triplet energy of the hole transporting material is larger than the triplet energy of the host, when the triplet energy of the hole transporting material and that of the host are compared.

### Sixth Exemplary Embodiment

Next, a sixth exemplary embodiment of the invention will be described.

In the description of the sixth exemplary embodiment, the same components as those in the first to fifth exemplary embodiments are denoted by the same reference numerals to simplify or omit description of the components. The fused hydrocarbon compound, the electron-donating dopant, the organic metal complex including an alkali metal and other compounds used in the sixth exemplary embodiment are the same compounds described in the first exemplary embodiment.

An organic EL device of the sixth exemplary embodiment may have a tandem device configuration in which at least two emitting units each including an emitting layer are provided. An intermediate unit (occasionally referred to as an intermediate conductive layer, charge generation layer, intermediate layer or CGL) is interposed between the two emitting units. Specifically, an organic EL device of the sixth exemplary embodiment includes an anode, a plurality of emitting units, intermediate units, an electron transporting zone and a cathode. The electron transporting zone is as described in the above exemplary embodiments. The blocking layer in the electron transporting zone and the emitting layer in the emitting unit adjacent to the blocking layer satisfy the relationship described in the first exemplary embodiment. An electron transporting zone can be provided in each emitting unit.

Specific examples of the organic EL device of the sixth exemplary embodiment are given below.

anode/first emitting unit (fluorescent-emitting layer)/intermediate unit/second emitting layer (fluorescent-emitting layer)/electron transporting zone/cathode

anode/first emitting unit (fluorescent-emitting layer)/electron transporting zone/intermediate unit/second emitting layer (fluorescent-emitting layer)/electron transporting zone/cathode

anode/first emitting unit (phosphorescent-emitting layer)/electron transporting zone/intermediate unit/second emitting layer (fluorescent-emitting layer)/electron transporting zone/cathode

anode/first emitting unit (phosphorescent-emitting layer)/intermediate unit/second emitting layer (fluorescent-emitting layer)/electron transporting zone/cathode

anode/first emitting unit (fluorescent-emitting layer)/electron transporting zone/intermediate unit/second emitting layer (phosphorescent-emitting layer)/electron transporting zone/cathode

anode/first emitting unit (fluorescent-emitting layer)/intermediate unit/second emitting layer (phosphorescent-emitting layer)/electron transporting zone/cathode

The emitting layer in each emitting unit may be formed of a single emitting layer, or may be provided by laminating the plurality of the emitting layers.

At least one of the electron transporting zone and the hole transporting zone may be interposed between two emitting units. Three or more emitting units may be provided, and two or more intermediate units may be provided. When three or more emitting units are present, an intermediate unit may not be, or may be interposed between all the emitting units.

The intermediate unit is formable of known material such as ones described in the specification of U.S. Pat. No. 7,358,661 and U.S. application Ser. No. 10/562,124 (U.S. Ser. No. 10/562,124).

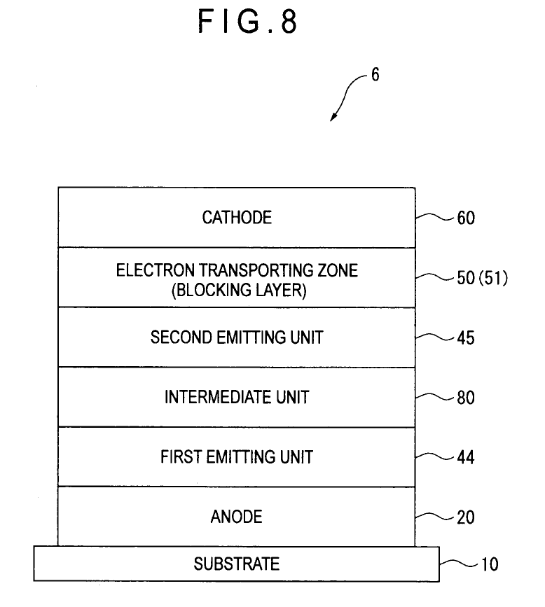

FIG. 8 schematically shows the organic EL device 6 according to the sixth exemplary embodiment. The organic EL device 6 includes a first emitting unit 44, an intermediate unit 80, a second emitting unit 45, the electron transporting zone 50 and the cathode 60 in sequential order from the anode 20. In the second emitting layer 42, an emitting layer is provided near the electron transporting zone 50. This emitting layer and the blocking layer 51 in the electron transporting zone 50 satisfy the relationship described in the first exemplary embodiment. As a result, the organic EL device 6 can also exhibit the functions (1) to (3) of the electron transporting zone as described in the first exemplary embodiment.

It should be noted that the present invention is not limited to the above description but may include any modification as long as such modification stays within a scope and a spirit of the present invention.

Although the hole transporting zone 30 is provided as a preferable example in the above exemplary embodiments, the hole transporting zone 30 may not be provided.

### EXAMPLES

Examples of the invention will be described below. However, the invention is not limited by these Examples.

### Fluorescent Organic Electroluminescence Device

### Example 1

An organic EL device according to Example 1 was manufactured as follows.

A glass substrate (size: 25 mm×75 mm×1.1-mm thick, manufactured by Geomatec Co., Ltd.) having an ITO transparent electrode (anode) was ultrasonic-cleaned in isopropyl alcohol for five minutes, and then UV/ozone-cleaned for 30 minutes. After the glass substrate having the transparent electrode line was cleaned, the glass substrate was mounted on a substrate holder of a vacuum deposition apparatus, so that a compound HT1 was initially formed onto a surface of the glass substrate where the transparent electrode line was provided so as to cover the transparent electrode. Thus, a 50-nm thick hole injecting layer was formed.

A compound HT2 was deposited on the hole injecting layer to form a 45-nm thick hole transporting layer. Thus, the hole transporting zone including the hole injecting layer and the hole transporting layer was formed.

A compound BH1 (the host) and a compound BD (the fluorescent dopant) were co-deposited on the hole transporting zone. Thus, a 25-nm thick emitting layer of blue emission was formed. A concentration of the compound BD in the emitting layer was 5 mass %.

Next, a compound PR1 (the fused hydrocarbon compound) and a compound Liq (the metal complex including an alkali metal) were co-deposited on the emitting layer. A 25-nm thick blocking layer was formed. A concentration of the compound Liq in the blocking layer was 50 mass %.

The compound Liq was deposited on the blocking layer to form a 1-nm thick electron injecting layer. Thus, the electron transporting zone including the blocking layer and the electron injecting layer was formed. When the blocking layer and the electron injecting layer were formed, the compound Liq was used in common. Accordingly, after formation of the blocking layer, deposition of the compound PR1 was stopped and only the compound Liq was deposited, thereby forming the electron injecting layer. With such a formation of the electron transporting zone, the electron transporting zone was formable by the smaller number of steps as compared with an electron transporting layer using a different material.

Moreover, metallic aluminum (Al) was deposited on the electron transporting zone to form an 80-nm thick cathode.

### Examples 2 to 4 and Comparatives 1 to 2

The organic EL devices according respectively to Examples 2 to 4 and Comparatives 1 to 2 were formed in the same manner as in Example 1 except that the materials, the thickness of each layer and the concentration of each luminescent material were changed as shown in Device Arrangement A and Table 1 below. Specifically, in Examples 2 to 4 and Comparatives 1 to 2, the fused hydrocarbon compound (represented by a compound X_{A} in the following Device Arrangement A) of the blocking layer in the organic EL device in Example 1 was replaced by compounds shown in Table 1 to prepare respective organic EL devices.

Device Arrangement A

Anode: ITO

Hole Injecting Layer: HT1 (50 nm)

Hole Transporting Layer: HT2 (45 nm)

Emitting Layer: BH1:BD (25 nm, 5%)

Blocking Layer: X_{A}:Liq (25 nm, 50%)

Electron Injecting Layer: Liq (1 nm)

Cathode: Al (80 nm)

The numerals in parentheses in Device Arrangement A indicate a thickness of each layer (unit: nm). The numerals represented by percentage in parentheses indicate a ratio (mass percentage) of the fluorescent material in each emitting layer.

TABLE 1

| | Example 1 | Example 2 | Example 3 | Example 4 | Comp. 1 | Comp. 2 |
|---|---|---|---|---|---|---|
| Compound X_{A} | PR1 | PR2 | PR3 | PR4 | BH2 | ET1 |

Chemical formulae of materials for the hole injecting layer, the hole transporting layer, the emitting layer, the blocking layer and the electron injecting layer used in Examples 1 to 4 and Comparatives 1 to 2 are shown below.

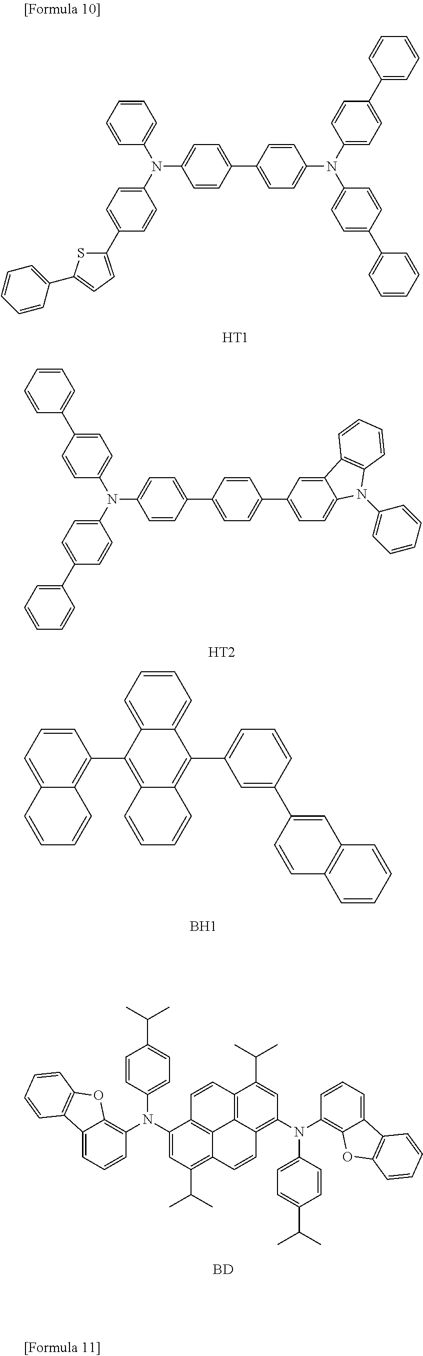

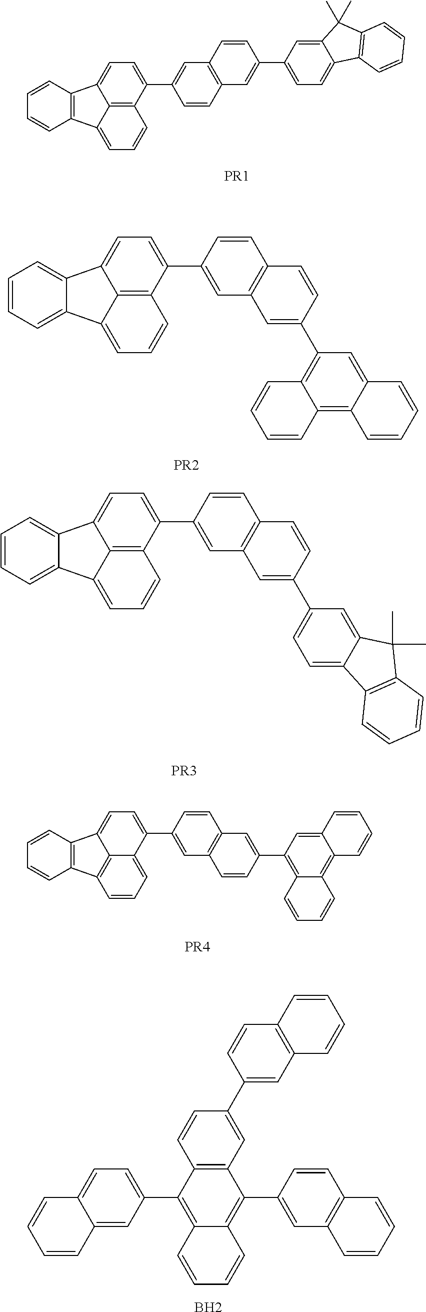

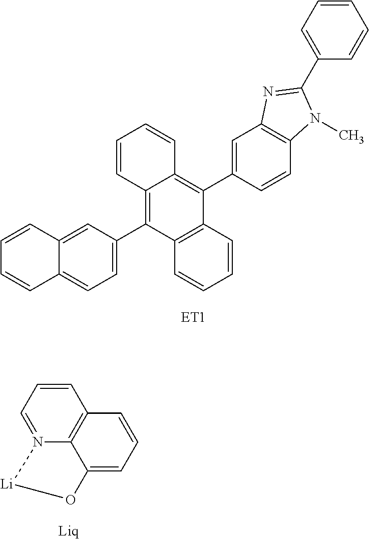

With respect to the fused hydrocarbon compound of the blocking layer in each of Examples 1 to 4 and Comparatives 1 to 2, triplet energy was measured. The results are shown in Table 2. Triplet energy of each material contained in the emitting layer was measured. The results are shown blow. GD refers to the compound (dopant) used in Example 13 and Comparative 12 described later.

Ir(piq)₃ EgT:2.1 eV

BD EgT:1.9 eV

BH1 EgT:1.8 eV

GD EgT:1.7 eV

Triplet energy (EgT) was obtained by the following method. The organic material was measured by a known method of measuring phosphorescence (e.g. a method described in “Hikarikagaku no Sekai (The World of Photochemistry)” (edited by The Chemical Society of Japan, 1993, on and near page 50). Specifically, the organic material was dissolved in a solvent (sample: 10 mol/L, EPA (diethylether:isopentane:ethanol=5:5:2 in volume ratio, each solvent in a spectroscopic grade), thereby forming a sample for phosphorescence measurement. The sample put into a quartz cell was cooled to 77K and was irradiated with exciting light, so that a wavelength of phosphorescence radiated therefrom was measured. A tangent line was drawn to be tangent to a rising section of the phosphorescence spectrum on the short-wavelength side, a wavelength value thereof was converted into energy value, and the converted energy value was defined as EgT. A spectrophotofluorometer F-4500 (manufactured by Hitachi, Ltd.) and optional accessories for low-temperature measurement were used for measurement. A measurement instrument is not limited to the above. A combination of a cooling device, a low-temperature container, an excited-light source, a light-accepting device may be used for measurement.

In the invention, the wavelength was converted using the following equation.

The conversion equation: EgT(eV)=1239.85/λ_{edge}

When the phosphorescence spectrum is expressed in coordinates of which ordinate axis indicates the phosphorescence intensity and of which abscissa axis indicates the wavelength, and a tangent is drawn to the rising section of the phosphorescence spectrum on the shorter wavelength side, “λ_{edge}” is a wavelength value (unit: nm) at the intersection of the tangent and the abscissa axis.

Next, voltage was applied on each of the organic EL devices according to

Examples 1 to 4 and Comparatives 1 to 2 such that a current density was 10 mA/cm², where a voltage value was measured. EL emission spectrum at that time was measured with a spectroradiometer (CS-1000, manufactured by Konica Minolta Holding, Inc.). Based on the obtained spectral radiance spectrum, luminous efficiency (L/J) and external quantum efficiency (EQE) were calculated. The results are shown in Table 2.

Further, device lifetime (LT95) was measured and evaluated. The results are shown in Table 2. The device lifetime was defined as time elapsed until the initial luminance intensity was decreased to 95%. The initial luminance intensity is a value at the current density of 8 mA/cm².

TABLE 2

| | EgT | Voltage | L/J | EQE | LT95 |
|---|---|---|---|---|---|
| | [eV] | [V] | [cd/A] | [%] | [h] |
| Example 1 | 2.2 | 4.20 | 9.70 | 8.80 | 350 |
| Example 2 | 2.3 | 4.00 | 10.00 | 9.50 | 330 |
| Example 3 | 2.3 | 4.40 | 9.30 | 8.80 | 300 |
| Example 4 | 2.3 | 4.10 | 10.30 | 9.60 | 250 |
| Comp. 1 | 1.8 | 3.70 | 8.70 | 8.30 | 50 |
| Comp. 2 | 1.8 | 4.10 | 8.10 | 7.70 | 33 |

As shown in Table 2, it was found that the organic EL devices according to the Examples 1 to 4 exhibited excellent device characteristics in drive voltage, luminous efficiency, external quantum efficiency and device lifetime.

In contrast, it was found that the organic EL devices of Comparatives 1 to 2 exhibited an extremely short device lifetime. Further, not all of the drive voltage, luminous efficiency and external quantum efficiency are satisfactory although a part of those may be superior to those of Examples 1 to 4.

### Phosphorescent Organic Electroluminescence Device

### Examples 5 to 7 and Comparatives 3 to 6

The organic EL devices according respectively to Examples 5 to 7 and Comparatives 3 to 6 were formed in the same manner as in Example 1 except that the materials, the thickness of each layer and the concentration of each luminescent material were changed as shown in Device Arrangement B and Table 3 below. Specifically, in Examples 5 to 7 and Comparatives 3 to 6, the fused hydrocarbon compound (represented by a compound X_{B} in the following Device Arrangement B) of the blocking layer in the organic EL device in Example 1 was replaced by compounds shown in Table 3. The emitting layer was formed as a layer exhibiting red emission.

Device Arrangement B

Anode: ITO

Hole Injecting Layer: HT3 (5 nm)

Hole Transporting Layer: HT4 (110 nm)

Emitting Layer: PR5:Ir(piq)₃ (45 nm, 8%)

Blocking Layer: X_{B}:Liq (30 nm, 50%)

Electron Injecting Layer: Liq (1 nm)

Cathode: Al (80 nm)

The numerals in parentheses in Device Arrangement A indicate a thickness of each layer (unit: nm). The numerals represented by percentage in parentheses indicate a ratio (mass percentage) of the phosphorescent material in each emitting layer.

TABLE 3

| | Example 5 | Example 6 | Example 7 | Comp. 3 | Comp. 4 | Comp. 5 | Comp. 6 |
|---|---|---|---|---|---|---|---|
| X_{B} | PR1 | PR5 | PR6 | BH3 | BH1 | ET2 | ET3 |

Chemical formulae of materials for the hole injecting layer, the hole transporting layer, the emitting layer, the blocking layer and the electron injecting layer used in Examples 5 to 7 and Comparatives 3 to 6 but not shown therein are shown below.

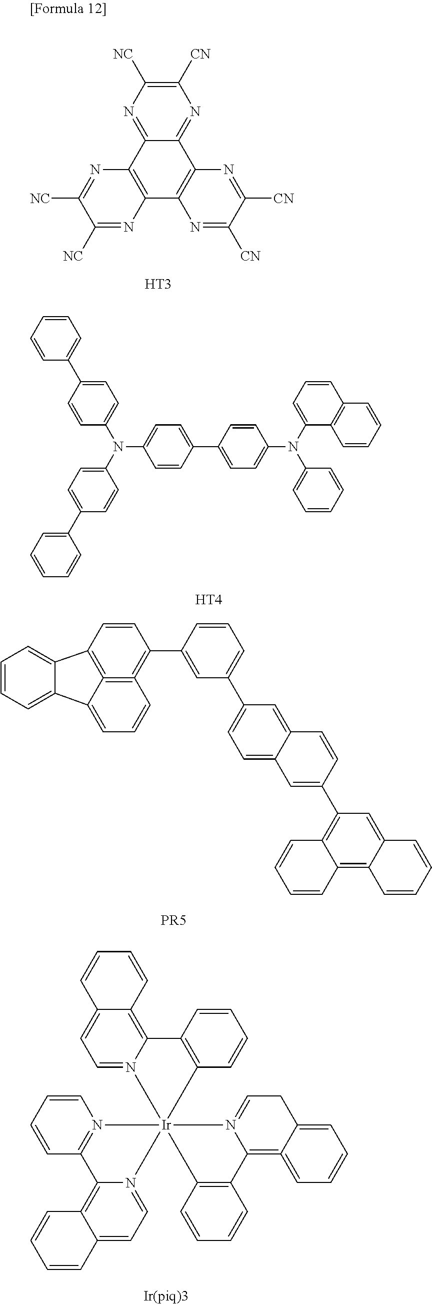

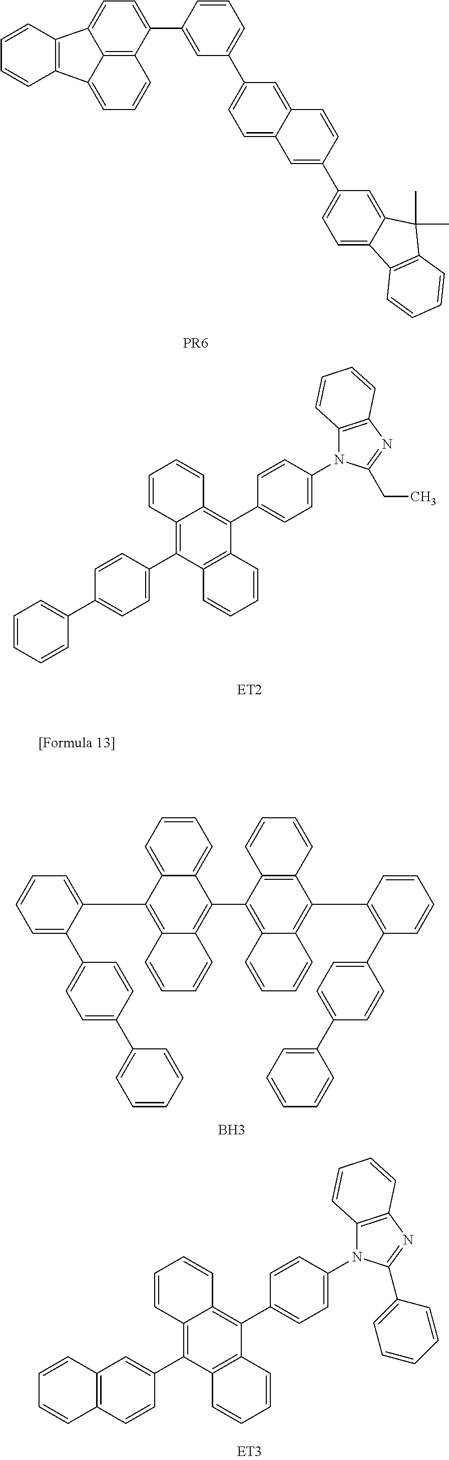

With respect to the fused hydrocarbon compound of the blocking layer in each of Examples 5 to 7 and Comparatives 3 to 6, triplet energy was measured in the same manner as in Example 1. The results are shown in Table 4.

With respect to the organic EL device in each of Examples 5 to 7 and Comparatives 3 to 6, voltage value, luminous efficiency (L/J), external quantum efficiency (EQE) and device lifetime (LT95) were measured in the same manner as in Example 1 and evaluated. The results are shown in Table 4. The initial luminance intensity was 2600 [cd/m²].

TABLE 4

| | EgT | Voltage | L/J | EQE | LT95 |
|---|---|---|---|---|---|
| | [eV] | [V] | [cd/A] | [%] | [h] |
| Example 5 | 2.2 | 4.24 | 10.69 | 13.83 | 500 |
| Example 6 | 2.3 | 5.20 | 10.28 | 13.49 | 900 |
| Example 7 | 2.3 | 5.15 | 10.85 | 13.07 | 280 |
| Comp. 3 | 1.8 | 6.45 | 9.68 | 12.65 | 400 |
| Comp. 4 | 1.8 | 6.93 | 9.35 | 11.99 | 450 |
| Comp. 5 | 1.8 | 4.26 | 10.02 | 13.57 | 40 |
| Comp. 6 | 1.8 | 4.60 | 11.60 | 12.47 | 85 |

As shown in Table 4, it was found that the organic EL devices according to the Examples 5 to 7 exhibited excellent device characteristics in drive voltage, luminous efficiency, external quantum efficiency and device lifetime.

In contrast, it was found that, in the organic EL devices of Comparatives 3 to 6, not all of the drive voltage, luminous efficiency, external quantum efficiency and device lifetime were satisfactory although a part of those may be superior to those of Examples 5 to 7.

The organic EL devices of Comparatives 3 and 4 had the lifetimes equivalent to the lifetimes of the organic EL devices of Examples. It is considered that, since the blocking layer in Comparatives 3 and 4 was formed of a fused hydrocarbon compound, the lifetime was not largely different from that in Examples 5 to 7.

In Comparatives 5 and 6, since electron transporting materials (ET2, ET3), which each contained a nitrogen-containing cyclic compound and exhibited a high electron transporting capability, were used as the blocking layer, the recombination region concentrated at the interface between the emitting layer and the hole transporting layer.

Accordingly, the lifetime was short and not enough for practical use although triplet excitons were not diffused in the electron transporting zone to exhibit a high efficiency.

### Examples 8 to 9 and Comparative 7

Organic EL devices of Examples 8 to 9 and Comparative 7 were manufactured in the same manner as in Example 5 except that a compound PR5 was replaced by a compound PR7 as the host of the emitting layer and the compound X_{B} of the blocking layer was changed as shown in Table 5.

TABLE 5

| | Example 8 | Example 9 | Comp. 7 |
|---|---|---|---|
| X_{B} | PR1 | PR5 | BH1 |

Chemical formulae of materials for the hole injecting layer, the hole transporting layer, the emitting layer, the blocking layer and the electron injecting layer used in Examples 8 to 9 and Comparative 7 but not shown therein are shown below.

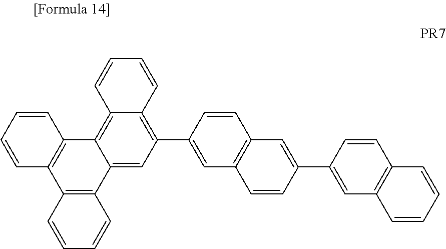

Next, with respect to the fused hydrocarbon compound of the blocking layer in each of Examples 8 to 9 and Comparative 7, triplet energy was measured in the same manner as in Example 1. The results are shown in Table 6.

With respect to the organic EL device in each of Examples 8 to 9 and Comparative 7, voltage value, luminous efficiency (L/J), external quantum efficiency (EQE) and device lifetime (LT95) were measured in the same manner as in Example 1 and evaluated. The results are shown in Table 6. The initial luminance intensity was 2600 [cd/m²].

TABLE 6

| | EgT | Voltage | L/J | EQE | LT95 |
|---|---|---|---|---|---|
| | [eV] | [V] | [cd/A] | [%] | [h] |
| Example 8 | 2.2 | 4.50 | 9.81 | 12.41 | 550 |
| Example 9 | 2.3 | 5.09 | 9.64 | 12.55 | 820 |
| Comp. 7 | 1.8 | 7.08 | 9.10 | 11.73 | 500 |

As shown in Table 6, it was found that the organic EL devices according to the Examples 8 to 9 exhibited excellent device characteristics in drive voltage, luminous efficiency, external quantum efficiency and device lifetime.

In contrast, it was found that, in the organic EL devices of Comparative 7, all of the drive voltage, luminous efficiency, external quantum efficiency and device lifetime were inferior to those of Examples 8 to 9.

The organic EL device of Comparative 7 had the lifetime equivalent to the lifetimes of the organic EL devices of Examples. It is considered that, since the blocking layer in Comparative 7 was formed of a fused hydrocarbon compound (BH1), the lifetime was not largely different from those in Examples.

### Examples 10 to 11 and Comparative 8

Organic EL devices of Examples 10 to 11 and Comparative 8 were manufactured in the same manner as in Example 5 except that the electron injecting layer provided between the cathode and the blocking layer was omitted and the compound X_{B} of the blocking layer was changed as shown in Table 7.

TABLE 7

| | Example 10 | Example 11 | Comp. 8 |
|---|---|---|---|
| X_{B} | PR5 | PR1 | BH1 |

Next, with respect to the fused hydrocarbon compound of the blocking layer in each of Examples 10 to 11 and Comparative 8, triplet energy was measured in the same manner as in Example 1. The results are shown in Table 8.

With respect to the organic EL device in each of Examples 10 to 11 and Comparative 8, voltage value, luminous efficiency (L/J), external quantum efficiency (EQE) and device lifetime (LT95) were measured/calculated in the same manner as in Example 1 and evaluated. The results are shown in Table 8. The initial luminance intensity was 2600 [cd/m²].

TABLE 8

| | EgT | Voltage | L/J | EQE | LT95 |
|---|---|---|---|---|---|
| | [eV] | [V] | [cd/A] | [%] | [h] |
| Example 10 | 2.3 | 5.68 | 9.98 | 13.35 | 220 |
| Example 11 | 2.2 | 4.52 | 10.84 | 14.22 | 120 |
| Comp. 8 | 1.8 | 7.15 | 9.29 | 11.82 | 140 |

As shown in Table 8, it was found that the organic EL devices according to the Examples 10 to 11 exhibited excellent device characteristics in drive voltage, luminous efficiency, external quantum efficiency and device lifetime.

In contrast, it was found that, in the organic EL device of Comparative 8, not all of the drive voltage, luminous efficiency, external quantum efficiency and device lifetime were satisfactory although a part of those may be superior to those of Examples 10 to 11.

The organic EL device of Comparative 8 had the lifetime equivalent to the lifetimes of the organic EL devices of Examples. It is considered that, since the blocking layer in Comparative 7 was formed of the fused hydrocarbon compound (BH1), the lifetime was not largely different from those in Examples.

Fluorescent and Phosphorescent Organic EL devices (Common Electron Transporting Zone)

### Examples 12 to 14 and Comparatives 9 to 11

In each of Examples 12 to 14 and Comparatives 9 to 11, an organic EL device having a device arrangement shown in Table 9 was manufactured on the glass substrate used in Example 1.

The numerals in parentheses in Table 9 indicate a thickness of each layer (unit: nm). The numerals represented by percentage in parentheses indicate a ratio (mass percentage) of an added component such as a dopant into each emitting layer.

Example 12 and Comparative 9 each provided a red phosphorescent organic EL device. Example 13 and Comparative 10 each provided a green fluorescent organic EL device. Example 14 and Comparative 11 each provided a blue fluorescent organic EL device.

TABLE 9

| | Device Arrangement |
|---|---|
| Example 12 | ITO/HT1(50)/HT2(45)/PR5:Ir(piq)3(45.8%)/ |
| | PR5:Liq(25.50%)/Liq(1)/Al(80) |
| Comp. 9 | ITO/HT1(50)/HT2(45)/PR5:Ir(piq)3(45.8%)/ |
| | BH3:Liq(25.50%)/Liq(1)/Al(80) |
| Example 13 | ITO/HT1(50)/HT2(45)/BH1:GD(25.5%)/ |
| | PR5:Liq(25.50%)/Liq(1)/Al(80) |
| Comp. 10 | ITO/HT1(50)/HT2(45)/BH1:GD(25.5%)/ |
| | BH3:Liq(25.50%)/Liq(1)/Al(80) |
| Example 14 | ITO/HT1(50)/HT2(45)/BH1:BD(25.5%)/ |
| | PR5:Liq(25.50%)/Liq(1)/Al(80) |
| Comp. 11 | ITO/HT1(50)/HT2(45)/BH1:BD(25.5%)/ |
| | BH4:Liq(25.50%)/Liq(1)/Al(80) |

Chemical formulae of GD used in Example 13 and Comparative 10 and BH4 used in Comparative 11 are shown below.

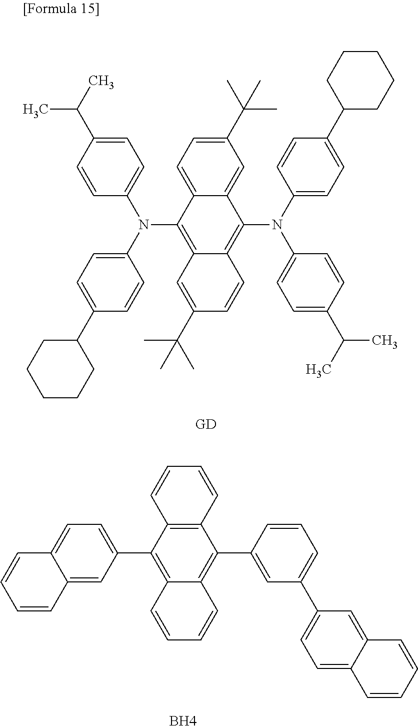

Next, the organic EL devices according to Examples 12 to 14 and Comparatives 9 to 11 were driven and drive voltages thereof at that time were measured. At this time, voltage was applied to each of the organic EL devices so that a current density was 10.00 mA/cm².

EL emission spectrum when the device was driven was measured by a spectroradiometer (CS-1000 manufactured by Konica Minolta Holding, Inc.). Based on the obtained spectral radiance spectrum, current efficiency (L/J) and external quantum efficiency (EQE) were calculated. The results are shown in Table 10.

TABLE 10

| | Voltage | L/J | EQE |
|---|---|---|---|
| | [V] | [cd/A] | [%] |
| Example 12 | 5.79 | 11.50 | 13.90 |
| Comp. 9 | 7.18 | 10.90 | 12.90 |
| Example 13 | 4.25 | 32.90 | 8.56 |
| Comp. 10 | 5.08 | 28.14 | 7.36 |
| Example 14 | 4.35 | 9.95 | 7.08 |
| Comp. 11 | 4.90 | 9.01 | 6.47 |

It was found that, in the organic EL devices of red, green and blue emission, even when the arrangements of the electron transporting zones in Examples 12 to 14 were the same and those in Comparatives 9 to 11 were the same, the organic EL device of red, green and blue emission in Examples 12 to 14 exhibited excellent device characteristics in drive voltage, current efficiency, and external quantum efficiency as shown in Table 10.

With respect to the lifetime, all the organic EL devices of Examples 12 to 14 and Comparatives 9 to 11 achieved a sufficiently long lifetime.

Fluorescent Organic EL device (Hole/Electron Transporting Zone including Electron-donating Dopant)

### Examples 15 to 16 and Comparatives 12 to 13

An organic device having a device arrangement shown in Table 11 was manufactured on the glass substrate (with no ITO film) used in Example 1. The organic EL devices respectively according to Examples 15 to 16 and Comparatives 12 to 13 had a so-called top-emission device arrangement in which APC functioned as a reflective electrode and light from the emitting layer was emitted from the top surface layer opposite to the glass substrate. CsF (cesium fluoride) as the electron-donating dopant was contained in the electron transporting zone.

The numerals in parentheses in Table 11 indicate a thickness of each layer (unit: nm). The numerals represented by percentage in parentheses indicate a ratio (mass percentage) of an added component such as a dopant into each emitting layer.

TABLE 11

| | Device Arrangement |
|---|---|
| Ex. 15 | APC/IZO(10)/HT3(30)/HT5:HT3(90, 1.5 wt %)/HT6(20)/ |
| | BH4:BD(25:5%)/PR5:CsF(35, 30 wt %)/MgAg(15, 10%)/ |
| | BH4(70) |
| Ex. 16 | APC/IZO(10)/HT3(30)/HT5:HT3(90, 1.5 wt %)/HT6(20)/ |
| | BH4:BD(25:5%)/PR5:CsF(35, 30 wt %)/MgAg(15, 10%)/ |
| | BH4(70) |
| Comp. | APC/IZO(10)/HT3(30)/HT5:HT3(90, 1.5 wt %)/HT6(20)/ |
| 12 | BH4:BD(25:3%)/BH4:CsF(35, 30 wt %)/MgAg(15, 10%)/ |
| | BH4(70) |
| Comp. | APC/IZO(10)/HT3(30)/HT5:HT3(90, 1.5 wt %)/HT6(20)/ |
| 13 | BH4:BD(25:3%)/BH4:CsF(35, 30 wt %)/MgAg(15, 10%)/ |
| | BH4(70) |

Compounds used in Examples 15 to 16 and Comparatives 12 to 13 are shown below.

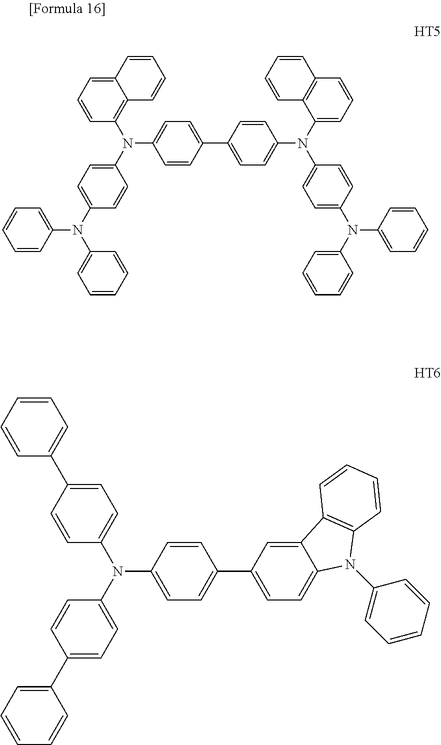

Next, the organic EL devices respectively according to Examples 15 to 16 and Comparatives 12 to 13 were driven and drive voltages thereof at that time were measured. At this time, voltage was applied to each of the organic EL devices so that a current density was 10.00 mA/cm².

EL emission spectrum when the device was driven was measured by a spectroradiometer (CS-1000 manufactured by Konica Minolta Holding, Inc.). Based on the obtained spectral radiance spectrum, CIE chromaticity, current efficiency L/J and external quantum efficiency EQE were calculated. The results are shown in Table 12.

TABLE 12

| | | | |
|---|---|---|---|
| Voltage | Chromaticity | L/J | EQE |

| | [V] | x | y | [cd/A] | [%] |
|---|---|---|---|---|---|
| Example 15 | 4.54 | 0.136 | 0.053 | 4.64 | 8.71 |
| Example 16 | 4.53 | 0.137 | 0.052 | 4.49 | 8.47 |
| Comp. 12 | 4.18 | 0.137 | 0.050 | 3.73 | 7.28 |
| Comp. 13 | 4.19 | 0.138 | 0.049 | 3.64 | 7.16 |

It was found that, also when not the organic metal complex including an alkali metal such as Liq in Example 1 but the electron-donating dopant such as CsF was used in the electron transporting zone, the organic EL devices of Examples 15 to 16 exhibited excellent characteristics in current efficiency and external quantum efficiency although drive voltage was slightly higher than those of the organic EL devices of Comparatives 12 to 13 as shown in Table 12.

With respect to the lifetime, all the organic EL devices of Examples 15 to 16 and Comparatives 12 to 13 had a sufficiently long lifetime.

### INDUSTRIAL APPLICABILITY

An organic EL device of the invention is applicable to a display panel, an illumination panel and the like which are demanded to have a high efficiency and a long lifetime.

### EXPLANATION OF CODES

1 organic electroluminescence device
10 substrate
20 anode
30 hole transporting zone
40 emitting layer
50 electron transporting zone
51 blocking layer
60 cathode

1. An organic electroluminescence device, comprising, in sequential order:
an anode,
an emitting layer,
an electron transporting zone, and
a cathode,
wherein the electron transporting zone comprises a blocking layer that is adjacent to the emitting layer,
the blocking layer comprises a fused hydrocarbon compound and at least one compound selected from the group consisting of an electron-donating dopant and an organic metal complex that comprises an alkali metal, and
a triplet energy of the fused hydrocarbon compound is 2.0 eV or more.

2. An organic electroluminescence device, comprising, in sequential order:
an anode,
an emitting layer,
an electron transporting zone, and
a cathode,
wherein the electron transporting zone comprises a blocking layer,
the blocking layer comprises a first organic thin-film layer and a second organic thin-film layer that are sequentially laminated on the emitting layer,
the first organic thin-film layer comprises a fused hydrocarbon compound,
the second organic thin-film layer comprises the fused hydrocarbon compound and at least one compound selected from the group consisting of an electron-donating dopant and an organic metal complex that comprises an alkali metal, and
a triplet energy of the fused hydrocarbon compound is 2.0 eV or more.

3. The organic electroluminescence device of claim 1,
wherein the blocking layer comprises an electron-donating dopant, which is at least one compound selected from the group consisting of an alkali metal, an alkaline earth metal, a rare-earth metal, an alkali metal compound, an alkaline earth metal compound, and a rare earth metal compound.

4. The organic electroluminescence device of claim 3,
wherein the electron donating dopant is at least one compound selected from the group consisting of an alkali metal oxide, an alkali metal halide, an alkaline earth metal oxide, an alkaline earth metal halide, a rare earth metal oxid; and a rare earth metal halide.

5. The organic electroluminescence device of claim 1,
wherein the emitting layer comprises a host and a dopant that has a fluorescent emission of a main peak wavelength of 550 nm or less.

6. The organic electroluminescence device of claim 5,
wherein a triplet energy (E^{T}_{d(F)}) of the dopant that has a fluorescent emission is larger than a triplet energy (E^{T}ₕ) of the host.

7. The organic electroluminescence device of claim 6,
wherein the triplet energy of the fused hydrocarbon compound is larger than the triplet energy (E^{T}ₕ) of the host.

8. The organic electroluminescence device of claim 1,
wherein the emitting layer comprises a host and a dopant that has a phosphorescent emission.

9. The organic electroluminescence device of claim 8,
wherein the triplet energy of the fused hydrocarbon compound is larger than a triplet energy (E^{T}_{d(P)}) of the dopant that has a phosphorescent emission.

10. The organic electroluminescence device of claim 1, wherein the fused hydrocarbon compound is of any of formulae (1) to (4): 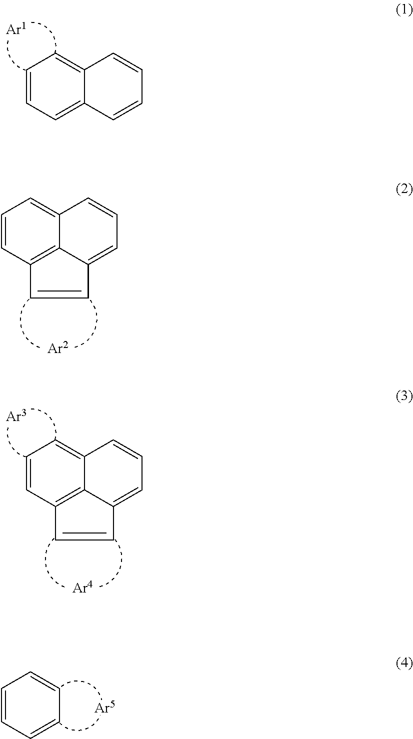
wherein Ar¹ to Ar⁵ are each independently a substituted or unsubstituted fused ring structure having from 4 to 16 ring carbon atoms.

11. The organic electroluminescence device of claim 1,
wherein the blocking layer comprises an organic metal complex comprising alkali metal, and
the organic metal complex is a compound of any of formulae (10) to (12): 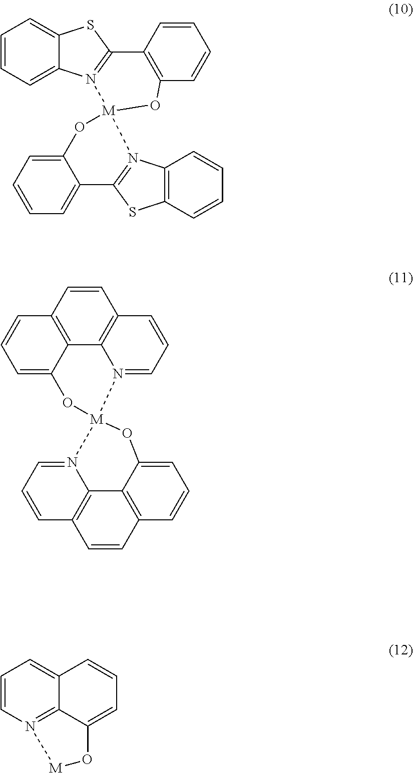
wherein M is an alkali metal atom.

12. The organic electroluminescence device of claim 1, further comprising:
a layer between the blocking layer and the cathode, the layer comprising the at least one compound selected from the group consisting of an electron-donating dopant and an organic metal complex.

13. The organic electroluminescence device of claim 1,
wherein in the blocking layer, a mass ratio of the fused hydrocarbon compound and the at least one compound selected from the group consisting of an electron-donating dopant and an organic metal complex is from 30:70 to 70:30.

14. The organic electroluminescence device of claim 2,
wherein the blocking layer comprises an electron-donating dopant, which is at least one compound selected from the group consisting of an alkali metal, an alkaline earth metal, a rare-earth metal, an alkali metal compound, an alkaline earth metal compound, and a rare earth metal compound.

15. The organic electroluminescence device of claim 14,
wherein the electron donating dopant is at least one compound selected from the group consisting of an alkali metal oxide, an alkali metal halide, an alkaline earth metal oxide, an alkaline earth metal halide, a rare earth metal oxide, and a rare earth metal halide.

16. The organic electroluminescence device of claim 2,
wherein the emitting layer comprises a host and a dopant that has a fluorescent emission of a main peak wavelength of 550 nm or less.

17. The organic electroluminescence device of claim 16,
wherein a triplet energy (E^{T}_{d(F)}) of the dopant that has a fluorescent emission is larger than a triplet energy (E^{T}ₕ) of the host.

18. The organic electroluminescence device of claim 17,
wherein the triplet energy of the fused hydrocarbon compound is larger than the triplet energy (E^{T}ₕ) of the host.

19. The organic electroluminescence device of claim 2,
wherein the emitting layer comprises a host and a dopant that has a phosphorescent emission.

20. The organic electroluminescence device of claim 19,
wherein the triplet energy of the fused hydrocarbon compound is larger than a triplet energy (E^{T}_{d(P)}) of the dopant that has a phosphorescent emission.

21. The organic electroluminescence device of claim 2, wherein the fused hydrocarbon compound is of any of formulae (1) to (4): 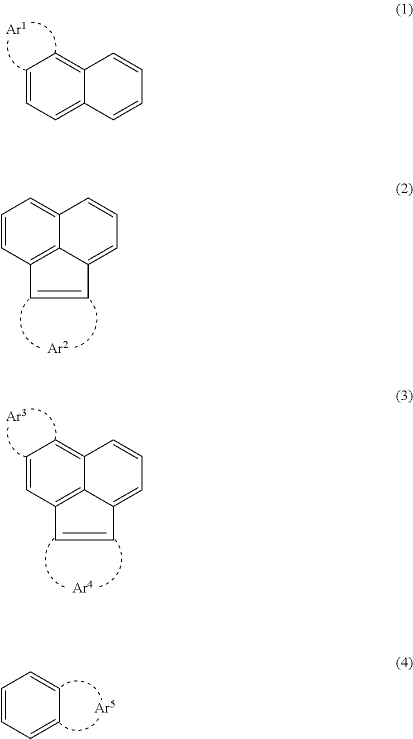
wherein Ar¹ to Ar⁵ are each independently a substituted or unsubstituted fused ring structure having from 4 to 16 ring carbon atoms.

22. The organic electroluminescence device of claim 2,
wherein the blocking layer comprises an organic metal complex comprising alkali metal, and
the organic metal complex is a compound of any of formulae (10) to (12): 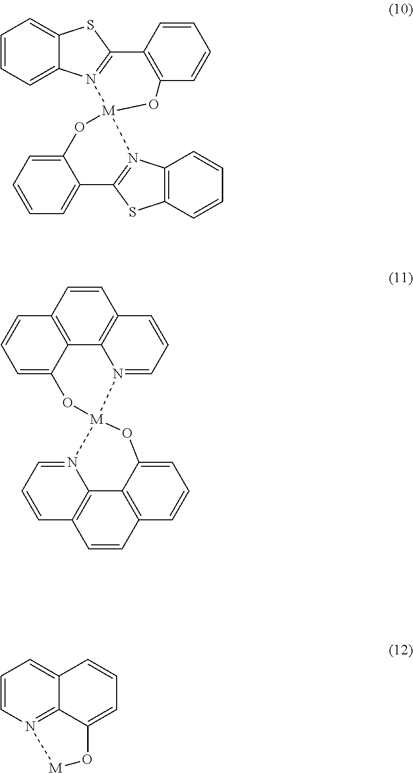
wherein M is an alkali metal atom.

23. The organic electroluminescence device of claim 2, further comprising:
a layer between the blocking layer and the cathode, the layer comprising the at least one compound selected from the group consisting of an electron-donating dopant and an organic metal complex.

24. The organic electroluminescence device of claim 2,
wherein, in the second organic thin-film layer, a mass ratio of the fused hydrocarbon compound and the at least one compound selected from the group consisting of an electron-donating dopant and an organic metal complex is from 30:70 to 70:30.
